(19) United States
(12) Patent Application Publication
(10) Pub. No.: US 2026/0153771 A1
(43) Pub. Date: Jun. 4, 2026

(54) ARRAY SUBSTRATE, DISPLAY PANEL AND DISPLAY APPARATUS

(71) Applicants: CHENGDU BOE DISPLAY SCI-TECH CO., LTD., Sichuan (CN); BOE Technology Group Co., Ltd., Beijing (CN)

(72) Inventors: Cong ZHANG, Beijing (CN); Guidong YANG, Beijing (CN); Yuanhui GUO, Beijing (CN); Jiajin LIU, Beijing (CN); Toshifumi YAGI, Beijing (CN); Lei LIU, Beijing (CN); Junying XIAO, Beijing (CN)

(21) Appl. No.: 18/715,431

(22) PCT Filed: Aug. 29, 2023
(86) PCT No.: PCT/CN2023/115605

§ 371 Date: May 31, 2024

(51) Int. Cl. G02F 1/1362; G02F 1/1368; H10D 86/40; H10D 86/60

(52) U.S. Cl. CPC G02F 1/136286; G02F 1/1368; H10D 86/441; H10D 86/60

(57) ABSTRACT

An array substrate, a display panel and a display apparatus. The array substrate includes: a base; a plurality of gate lines disposed on a side of the base and extending along a first direction; data lines extending along a second direction; and pixel electrodes. The pixel electrodes include a first pixel electrode at a side of the gate line and a second pixel electrode at the other side of the gate line. The first pixel electrode includes a first sub-pixel electrode and a second sub-pixel electrode arranged along the first direction, and the second pixel electrode includes a third sub-pixel electrode and a fourth sub-pixel electrode arranged along the first direction. One of the first sub-pixel electrode or the second sub-pixel electrode is electrically connected with one of the third sub-pixel electrode or the fourth sub-pixel electrode.

The application is a National Stage of International Application No. PCT/CN2023/115605, filed on Aug. 29, 2023, all of which is hereby incorporated by reference in its entirety.

### TECHNICAL FIELD

The disclosure relates to the field of semiconductor technology, in particular to an array substrate, a display panel and a display apparatus.

### BACKGROUND

The name of ultraviolet induced multi-domain vertical alignment (UV2A) is derived from the multiplication of ultraviolet (UV) and the vertical alignment (VA) mode of liquid crystal panels. The UV2A technology can precisely control the alignment of liquid crystal molecules through ultraviolet light, significantly improving light transmittance.

The key to the UV2A technology lies in the use of a special polymer material as an alignment film, allowing for high-precision control of liquid crystal molecules to tilt along the direction of ultraviolet light. The precision unit is in picometer (one trillionth of a meter). The advantage of UV2A technology lies in its simple structure, with a liquid crystal panel having a flat and seamless design. This “dream of liquid crystal technologists” was discussed as early as 30 years ago. It is only in recent times, with the availability of new materials, production equipment, and improved processing processes, that this dream has been realized. The simple construction of the liquid crystal panel not only enhances production efficiency but also offers many advantages in image quality.

### SUMMARY

Embodiments of the disclosure provide an array substrate, a display panel and a display apparatus.

The array substrate includes: a base; a plurality of gate lines disposed at a side of the base and extending along a first direction; a plurality of data lines extending along a second direction; and a plurality of pixel electrodes. The pixel electrode includes a first pixel electrode at a side of the gate line and a second pixel electrode at the other side of the gate line; and the first pixel electrode includes a first sub-pixel electrode and a second sub-pixel electrode arranged along the first direction, and the second pixel electrode includes a third sub-pixel electrode and a fourth sub-pixel electrode arranged along the first direction. One of the first sub-pixel electrode or the second sub-pixel electrode is electrically connected with one of the third sub-pixel electrode or the fourth sub-pixel electrode.

In a possible implementation, the array substrate further includes a plurality of transistors; where the transistors electrically connected with the same pixel electrode are electrically connected with the same data line and the same gate line. The second sub-pixel electrode is located at a side of the first sub-pixel electrode away from the data line in electrically connection; the fourth sub-pixel electrode is located at a side of the third sub-pixel electrode away from the data line in electrically connection; and the first sub-pixel electrode is electrically connected with the fourth sub-pixel electrode.

In a possible implementation, the array substrate includes a first signal line extending along the second direction. The plurality of transistors include a first transistor, a second transistor and a third transistor. A control electrode of the first transistor is electrically connected with the gate line, a first electrode of the first transistor is electrically connected with the data line, and a second electrode of the first transistor is electrically connected with the first sub-pixel electrode and the fourth sub-pixel electrode. A control electrode of the second transistor is electrically connected with the gate line, a first electrode of the second transistor is electrically connected with the data line, and a second electrode of the second transistor is electrically connected with the second sub-pixel electrode and the third sub-pixel electrode. A control electrode of the third transistor is electrically connected with the gate line, a first electrode of the third transistor shares the second electrode of the second transistor, and a second electrode of the third transistor shares the first signal line.

In a possible implementation, the pixel electrode further includes a first sub-pixel electrode convex portion connected with a side of the first sub-pixel electrode facing the third sub-pixel electrode; where the second electrode of the first transistor is electrically connected with the first sub-pixel electrode through the first sub-pixel electrode convex portion.

In a possible implementation, the pixel electrode further includes a connection portion connecting the first sub-pixel electrode and the fourth sub-pixel electrode; where the connection portion includes a first connecting portion extending along the second direction and a second connecting portion extending along a third direction; where the third direction intersect with the first direction and the second direction. One end of the first connecting portion is electrically connected with one end of the first sub-pixel electrode facing the third sub-pixel electrode, the other end of the first connecting portion is electrically connected with one end of the second connecting portion; and the other end of the second connecting portion is electrically connected with one end of the fourth sub-pixel electrode facing the second sub-pixel electrode.

In a possible implementation, the pixel electrode further includes a third sub-pixel electrode convex portion connected with a side of the third sub-pixel electrode facing the first sub-pixel electrode. The second electrode of the second transistor is electrically connected with the third sub-pixel electrode through the third sub-pixel electrode convex portion.

In a possible implementation, the pixel electrode further includes a second sub-pixel electrode extension portion extending along the second direction, and a second sub-pixel electrode convex portion. One end of the second sub-pixel electrode extension portion is electrically connected with one end of the second sub-pixel electrode facing the fourth sub-pixel electrode, and the other end of the second sub-pixel electrode extension portion is electrically connected with the second sub-pixel electrode convex portion. The second electrode of the second transistor is electrically connected with the second sub-pixel electrode through the second sub-pixel electrode convex portion.

In a possible implementation, an extension direction of the second sub-pixel electrode extension portion is parallel to an extension direction of the first connecting portion.

In a possible implementation, the second sub-pixel electrode convex portion has an outer edge extending along the first direction and located at a side away from the second sub-pixel electrode; and the third sub-pixel electrode convex portion has an outer edge extending along the first direction and located at the side away from the third sub-pixel electrode. An extension line of the outer edge of the second sub-pixel electrode convex portion coincides with an extension line of the outer edge of the third sub-pixel electrode convex portion; or, the extension line of the outer edge of the second sub-pixel electrode convex portion at least partially overlaps with the third sub-pixel electrode convex portion; or, the extension line of the outer edge of the third sub-pixel electrode convex portion at least partially overlaps with the second sub-pixel electrode convex portion.

In a possible implementation, a line connecting a center of the third sub-pixel electrode convex portion and a center of the first sub-pixel electrode convex portion is parallel to the second direction.

In a possible implementation, the second electrode of the first transistor includes a first portion extending along the first direction. An orthographic projection of the first portion of the first transistor on the base has an overlapping area with an orthographic projection of the first sub-pixel electrode convex portion on the base.

In a possible implementation, the second electrode of the second transistor includes a first portion extending along the first direction, and a second portion extending along the second direction and electrically connected with one end of the first portion of the second transistor. An orthographic projection of the first portion of the second transistor on the base has an overlapping area with an orthographic projection of the third sub-pixel electrode convex portion on the base; and an orthographic projection of the second portion of the second transistor on the base has an overlapping area with an orthographic projection of the second sub-pixel electrode convex portion on the base.

In a possible implementation, at least part of the orthographic projection of the second portion of the second transistor on the base overlaps with at least part of an orthographic projection of the second sub-pixel electrode extension portion on the base.

In a possible implementation, the first signal line includes a recessed portion. At least part of the orthographic projection of the second portion of the second transistor on the base is located in a region surrounded by an orthographic projection of the recessed portion on the base.

In a possible implementation, the first signal line includes a first signal portion, a second signal portion, and a third signal portion that are sequentially arranged along the second direction; a fourth signal portion extending along the first direction and connected with the second signal portion and the first signal portion; and a fifth signal portion extending along the first direction and connected with the second signal portion and the third signal portion. An extension line of the first signal portion coincides with an extension line of the third signal portion, and an extension line of the second signal portion does not coincide with the extension line of the first signal portion. The second signal portion, the fourth signal portion, and the fifth signal portion form the recessed portion; and the fourth signal portion and/or the fifth signal portion at least partially overlaps with the pixel electrode.

In a possible implementation, the array substrate further includes a first common line located at a side of the gate line and extending along the first direction. The plurality of transistors include a first transistor, a second transistor and a third transistor electrically connected with the data line. A control electrode of the first transistor is electrically connected with the gate line, a first electrode of the first transistor is electrically connected with the data line, and a second electrode of the first transistor is electrically connected with the first sub-pixel electrode and the fourth sub-pixel electrode. A control electrode of the second transistor is electrically connected with the gate line, a first electrode of the second transistor is electrically connected with the data line, and a second electrode of the second transistor is electrically connected with the second sub-pixel electrode and the third sub-pixel electrode. A control electrode of the third transistor is electrically connected with the gate line, a first electrode of the third transistor shares the second electrode of the second transistor, and a second electrode of the third transistor is electrically connected with the first common line.

In a possible implementation, the pixel electrode further includes a connection portion connecting the first sub-pixel electrode and the fourth sub-pixel electrode, and a first lapping portion connected with the connection portion. The connection portion includes: a third connecting portion and a fourth connecting portion extending along the first direction, and a fifth connecting portion extending along the second direction. One end of the third connecting portion is connected with the first sub-pixel electrode, one end of the fourth connecting portion is connected with the fourth sub-pixel electrode, one end of the fifth connecting portion is connected with the other end of the third connecting portion, and the other end of the fifth connecting portion is connected with the other end of the fourth connecting portion; the first lapping portion is electrically connected with the third connecting portion and located at a side away from the connected first sub-pixel electrode. The second electrode of the first transistor is electrically connected with the first sub-pixel electrode and the fourth sub-pixel electrode through the first lapping portion.

In a possible implementation, the pixel electrode further includes a first transfer portion extending along the first direction, a second transfer portion extending along the second direction, and a second lapping portion. One end of the first transfer portion is electrically connected with one end of the second sub-pixel electrode facing the fourth sub-pixel electrode, and the other end of the first transfer portion is electrically connected with one end of the second transfer portion; The other end of the second transfer portion is electrically connected with the second lapping portion. The second electrode of the second transistor is electrically connected with the second sub-pixel electrode through the second lapping portion.

In a possible implementation, an extension direction of the second transfer portion is parallel to an extension direction of the fifth connecting portion.

In a possible implementation, the pixel electrode further includes a third transfer portion extending along the first direction and a third lapping portion. One end of the third transfer portion is electrically connected with one end of the third sub-pixel electrode facing the first sub-pixel electrode, and the other end of the third transfer portion is electrically connected with the third lapping portion. The second electrode of the second transistor is electrically connected with the third sub-pixel electrode through the third lapping portion.

In a possible implementation, a first gap is provided between the third connecting portion and the first pixel electrode; a second gap is provided between the fourth connecting portion and the second pixel electrode; a third gap is provided between the first transfer portion and the first pixel electrode; and a fourth gap is provided between the third transfer portion and the second pixel electrode.

In a possible implementation, the array substrate further includes a fourth lapping portion. The second electrode of the third transistor is electrically connected with the first common line through the fourth lapping portion.

In a possible implementation, the fourth lapping portion has an outer edge extending along the first direction; the second lapping portion has an outer edge extending along the first direction; the first lapping portion has an outer edge extending along the second direction; and the third lapping portion has an outer edge extending along the second direction. An extension line of the outer edge of the fourth lapping portion coincides with an extension line of the outer edge of the second lapping portion; and an extension line of the outer edge of the first lapping portion coincides with an extension line of the outer edge of the third lapping portion.

In a possible implementation, the second electrode of the first transistor includes a first portion extending along the first direction. An orthographic projection of the first portion of the first transistor on the base has an overlapping area with an orthographic projection of the first lapping portion on the base.

In a possible implementation, the second electrode of the second transistor includes: a first portion extending along the first direction, and a second portion extending along the second direction and electrically connected with one end of the first portion of the second transistor. An orthographic projection of the first portion of the second transistor on the base has an overlapping area with an orthographic projection of the third lapping portion on the base; and an orthographic projection of the second portion of the second transistor on the base has an overlapping area with an orthographic projection of the second lapping portion on the base.

In a possible implementation, the array substrate further includes a first common line located at a side of the gate line and extending along the first direction; where the first common line is disconnected at an intersection with the date line.

In a possible implementation, the array substrate further includes a second common line group connected with the first common line and extending towards a side away from the gate line; where the second common line group includes two second common lines. An orthographic projection of the data line on the base has an overlapping area with an orthographic projection of a gap between the two second common lines of the same second common line group on the base.

In a possible implementation, the array substrate further includes a third common line located at the other side of the gate line and extending along the first direction, and a fourth common line group connected with the third common line and extending towards a side away from the gate line. The third common line is disconnected at an intersection with the data line. The fourth common line group includes two fourth common lines, the orthographic projection of the data line on the base has an overlapping area with an orthographic projection of a gap between the two fourth common lines of the same fourth common line group on the base.

In a possible implementation, the array substrate further includes a fifth common line extending along the first direction and electrically connected with the second common lines. An orthographic projection of the fifth common line on the base passes through a central area of an orthographic projection of the second pixel electrode on the base.

In a possible implementation, the array substrate further includes a sixth common line extending along the first direction and electrically connected with the fourth common lines. An orthographic projection of the sixth common line on the base passes through a central area of an orthographic projection of the first pixel electrode on the base.

In a possible implementation, the first sub-pixel electrode and the second sub-pixel electrode each includes: a first sub-electrode portion and a second sub-electrode portion arranged along the second direction. The third sub-pixel electrode and the fourth sub-pixel electrode each includes: a third sub-electrode portion and a fourth sub-electrode portion arranged along the second direction. The first sub-electrode portion, the second sub-electrode portion, the third sub-electrode portion, and the fourth sub-electrode portion each has multiple slits. An extension direction of the slits in the first sub-electrode portion is the same as that in the fourth sub-electrode portion, and an extension direction of the slits in the second sub-electrode portion is the same as that in the third sub-electrode portion.

In a possible implementation, a length of each of the slits in a direction perpendicular to the extension direction range from 2 μm to 4 μm.

In a possible implementation, shapes of orthographic projections of the first sub-pixel electrode, the second sub-pixel electrode, the third sub-pixel electrode, and the fourth sub-pixel electrode on the base all are a rectangular.

In a possible implementation, an orthographic projection of the first sub-electrode portion, an orthographic projection of the second sub-electrode portion, an orthographic projection of the third sub-electrode portion, and an orthographic projection of the fourth sub-electrode portion on the base all have a trapezoidal shape. In the first sub-pixel electrode and the fourth sub-pixel electrode, top edges of the first sub-electrode portion of the trapezoidal shape and the second sub-electrode portion of the trapezoidal shape face each other. In the second sub-pixel electrode and the third sub-pixel electrode, bottom edges of the first sub-electrode portion of the trapezoidal shape and the second sub-electrode portion of the trapezoidal shape face each other.

In a possible implementation, an orthographic projection of the first sub-electrode portion, an orthographic projection of the second sub-electrode portion, an orthographic projection of the third sub-electrode portion, and an orthographic projection of the fourth sub-electrode portion on the base all have a trapezoidal shape. In the first sub-pixel electrode and the fourth sub-pixel electrode, bottom edges of the first sub-electrode portion of the trapezoidal shape and the second sub-electrode portion of the trapezoidal shape face each other; and in the second sub-pixel electrode and the third sub-pixel electrode, top edges of the first sub-electrode portion of the trapezoidal shape and the second sub-electrode portion of the trapezoidal shape face each other.

In a possible implementation, the first sub-pixel electrode includes: a first body portion and a second body portion extending along the second direction and connected with each other, a first side portion extending along the first direction, a plurality of first branch portions extending along a fourth direction and starting from the first body portion and the first side portion, and a plurality of second branch portions extending along a fifth direction and starting from the second body portion and the first side portion. The second sub-pixel electrode includes: a third body portion and a fourth body portion extending along the second direction and connected with each other, a fifth body portion extending along the first direction and connected with one end of the third body portion, a sixth body portion extending along the first direction and connected with one end of the fourth body portion, a plurality of third branch portions extending along the fourth direction and starting from the third body portion and the fifth body portion, and a plurality of fourth branch portions extending along the fifth direction and starting from the fourth body portion and the sixth body portion. Here, the plurality of first branch portions and the plurality of third branch portions are arranged in a form of crossed fingers, and the plurality of second branch portions and the plurality of fourth branch portions are arranged in the form of crossed fingers. The third sub-pixel electrode includes: a seventh body portion and an eighth body portion extending along the second direction and connected with each other, a ninth body portion extending along the first direction and connected with one end of the seventh body portion, a tenth body portion extending along the first direction and connected with one end of the eighth body portion, a plurality of fifth branch portions extending along the fourth direction and starting from the seventh body portion and the ninth body portion, and a plurality of sixth branch portions extending along the fifth direction and starting from the eighth body portion and the tenth body portion. The fourth sub-pixel electrode includes: an eleventh body portion and a twelfth body portion extending along the second direction and connected with each other, a second side portion extending along the first direction, a plurality of seventh branch portions extending along the fourth direction and starting from the eleventh body portion and the second side portion, and a plurality of eighth branch portions extending along the fifth direction and starting from the twelfth body portion and the second side portion. Here, the plurality of fifth branch portions and the plurality of seventh branch portions are arranged in the form of crossed fingers, and the plurality of sixth branch portions and the plurality of eighth branch portions are arranged in the form of crossed fingers.

In a possible implementation, the array substrate further includes a first conductive layer at a side of the pixel electrode facing the base. The first conductive layer includes a first hollowed-out structure, a second hollowed-out structure, a third hollowed-out structure, and a fourth hollowed-out structure. At least part of an orthographic projection of the first hollowed-out structure on the base overlaps with at least part of an orthographic projection of the first sub-electrode portion on the base; at least part of an orthographic projection of the second hollowed-out structure on the base overlaps with at least part of an orthographic projection of the second sub-electrode portion on the base; at least part of an orthographic projection of the third hollowed-out structure on the base overlaps with at least part of an orthographic projection of the third sub-electrode portion on the base; and at least part of an orthographic projection of the fourth hollowed-out structure on the base overlaps with at least part of an orthographic projection of the fourth sub-electrode portion on the base.

Embodiments of the disclosure further provide a display panel, including the array substrate according to the embodiments of the disclosure, and a counter substrate arranged opposite to the array substrate, where the counter substrate is provided with a common electrode layer.

Embodiments of the disclosure further provide a display apparatus, including the display panel according to the embodiments of the disclosure.

### BRIEF DESCRIPTION OF FIGURES

FIG. 1A is a first one of top views of the array substrate provided in embodiments of the disclosure.

FIG. 1B is an enlarged view of a dotted box S1 in FIG. 1A.

FIG. 1C is a schematic single-layer diagram of a gate line layer in FIG. 1A.

FIG. 1D is a schematic single-layer diagram of an active layer in FIG. 1A.

FIG. 1E is a schematic single-layer diagram of data lines in FIG. 1A.

FIG. 1F is a schematic single-layer diagram of a first insulation layer in FIG. 1A.

FIG. 1G is a schematic single-layer diagram of pixel electrodes in FIG. 1A.

FIG. 1H is a schematic diagram of a simulation of the light effect that corresponds FIG. 1A.

FIG. 2A is a second one of top views of the array substrate provided in embodiments of the disclosure.

FIG. 2B is an enlarged view of a dotted box S1 in FIG. 2A.

FIG. 2C is a schematic single-layer diagram of a gate line layer in FIG. 2A.

FIG. 2D is a schematic single-layer diagram of an active layer in FIG. 2A.

FIG. 2E is a schematic single-layer diagram of data lines in FIG. 2A.

FIG. 2F is a schematic single-layer diagram of a first insulation layer in FIG. 2A.

FIG. 2G is a schematic single-layer diagram of pixel electrodes in FIG. 2A.

FIG. 2H is a schematic diagram of a simulation of the light effect that corresponds to FIG. 2A.

FIG. 2I is a schematic diagram of a cross-section of FIG. 2B along the dashed line EF.

FIG. 3A is a third one of top views of the array substrate provided in embodiments of the disclosure.

FIG. 3B is an enlarged view of a dotted box S1 in FIG. 3A.

FIG. 3C is a schematic single-layer diagram of a gate line layer in FIG. 3A.

FIG. 3D is a schematic single-layer diagram of an active layer in FIG. 3A.

FIG. 3E is a schematic single-layer diagram of data lines in FIG. 3A.

FIG. 3F is a schematic single-layer diagram of a first insulation layer in FIG. 3A.

FIG. 3G is a schematic single-layer diagram of pixel electrodes in FIG. 3A.

FIG. 3H is a schematic diagram of a simulation of the light effect that corresponds to FIG. 3A.

FIG. 4A is a fourth one of top views of the array substrate provided in embodiments of the disclosure.

FIG. 4B is an enlarged view of a dotted box S1 in FIG. 4A.

FIG. 4C is a schematic single-layer diagram of a gate line layer in FIG. 4A.

FIG. 4D is a schematic single-layer diagram of an active layer in FIG. 4A.

FIG. 4E is a schematic single-layer diagram of data lines in FIG. 4A.

FIG. 4F is a schematic single-layer diagram of a first insulation layer in FIG. 4A.

FIG. 4G is a schematic single-layer diagram of pixel electrodes in FIG. 4A.

FIG. 4H is a schematic diagram of a simulation of the light effect that corresponds to FIG. 4A.

FIG. 5A is a fifth one of top views of the array substrate provided in embodiments of the disclosure.

FIG. 5B is an enlarged view of a dotted box S1 in FIG. 5A.

FIG. 5C is a schematic single-layer diagram of a gate line layer in FIG. 5A.

FIG. 5D is a schematic single-layer diagram of an active layer in FIG. 5A.

FIG. 5E is a schematic single-layer diagram of data lines in FIG. 5A.

FIG. 5F is a schematic single-layer diagram of a first insulation layer in FIG. 5A.

FIG. 5G is a schematic single-layer diagram of pixel electrodes in FIG. 5A.

FIG. 5H is a schematic diagram of a simulation of the light effect that corresponds to FIG. 5A.

FIG. 6A is a sixth one of top views of the array substrate provided in embodiments of the disclosure.

FIG. 6B is an enlarged view of a dotted box S1 in FIG. 6A.

FIG. 6C is a schematic single-layer diagram of a gate line layer in FIG. 6A.

FIG. 6D is a schematic single-layer diagram of an active layer in FIG. 6A.

FIG. 6E is a schematic single-layer diagram of data lines in FIG. 6A.

FIG. 6F is a schematic single-layer diagram of a first insulation layer in FIG. 6A.

FIG. 6G is a schematic single-layer diagram of a first conductive layer in FIG. 6A.

FIG. 6H is a schematic single-layer diagram of a second insulation layer in FIG. 6A.

FIG. 6I is a schematic single-layer diagram of pixel electrodes in FIG. 6A.

FIG. 6J is a schematic diagram of a black matrix in FIG. 6A.

FIG. 6K is a schematic diagram of a simulation of the light effect that corresponds to FIG. 6A.

FIG. 7 schematically shows dark fringes in a conventional 8-domain structure.

FIG. 8 schematically shows dark fringes in an array substrate provided by embodiments of the disclosure.

FIG. 9 is a schematic diagram of the sub-pixel equivalent circuit provided in embodiments of the disclosure.

FIG. 10 is a cross-sectional view of a display panel provided in embodiments of the disclosure.

### DETAILED DESCRIPTION

In order to make the objectives, technical solutions, and advantages of embodiments of the disclosure clearer, the technical solution of the embodiments of the disclosure will be described clearly and comprehensively in conjunction with the accompanying drawings. Clearly, the described embodiments are part of embodiments of the disclosures and not all embodiments. Based on the described embodiments of the disclosure, all other embodiments that ordinary skilled in the art can obtain without creative effort fall within the scope of protection of the disclosure. Implementation can take various forms, and those skilled in the art can easily understand that methods and content can be transformed into one or more forms without departing from the purpose and scope of the disclosure. Therefore, the disclosure should not be interpreted as limited to the content described in the embodiments below. In cases where there is no conflict, embodiments and features of embodiments in the disclosure can be combined in any way.

Unless indicated otherwise, technical terms or scientific terms used in the disclosure should be understood in the general sense by those skilled in the art. Terms like “first,” “second,” and similar words do not imply any order, quantity, or importance but are used to distinguish different components. Terms like “including” or “comprising” indicate that a listed element or object before the term covers those listed after the term, and their equivalent, without excluding other elements or objects. Terms like “connected” or “coupled” are not limited to physical or mechanical connections but can include electrical connections, whether direct or indirect.

Expressions like “approximately” or “substantially the same” include a specified value and mean an acceptable range of deviation determined for specific values when considering the discussed measurement and errors (i.e., limitations of the measurement system) related to the measurement of a specific parameter by ordinary skilled in the art. For example, “substantially the same” may mean that the difference relative to the stated value is within one or more standard deviation ranges, or within ±30%, 20%, 10%, or 5%. In the description, “substantially the same” can refer to cases where the numerical values differ by 10% or less.

In the drawings, for clarity, thicknesses of layers, films, panels, regions, etc., are magnified. Exemplary embodiments are described with reference to cross-sectional views of schematic diagrams as idealized implementations. Thus, deviations in the shape of the drawings, anticipated as results of manufacturing technology and/or tolerances, are considered. Therefore, embodiments described herein should not be interpreted as limited to the specific shapes of the regions shown in this description but include deviations in the shapes caused by manufacturing, For example, flat areas shown in the figures may typically have rough and/or non-linear features. Additionally, sharp angles depicted may be circular. Thus, the regions shown in the figures are essentially indicative, and their shapes do not intend to depict the precise shapes of the regions and do not intend to limit the scope of the claims.

For convenience, terms indicating orientation or positional relationships such as “middle”, “upper”, “lower”, “front”, “back”, “vertical”, “horizontal”, “top”, “bottom”, “inner”, “outer” etc., are used in the description to describe the positional relationship of the constituent elements with reference to the drawings. It is solely for facilitating the description and simplifying the description, not indicating or implying that the device or component referred to must have a specific orientation, and be constructed and operated in a specific orientation. Therefore, it should not be understood as a limitation to the disclosure. The positional relationship of the constituent elements can be appropriately changed according to the described direction of the constituent elements. Thus, not limited to the terms described in the description, they can be appropriately replaced depending on the circumstances.

In the description, unless otherwise specified and limited, terms such as “installation”, “connected”, and “coupled to” should be broadly understood. For example, it can be a fixed connection, or a detachable connection, or an integral connection; it can be a mechanical connection, or an electrical connection; it can be directly connected, or indirectly connected through an intermediate, or connected internally in two components. For ordinary skilled in the art, the meanings of these terms in the disclosure can be understood according to the circumstances.

In the description, “electrical connection” includes the situation where constituent elements are connected through an element with some electrical action. There is no specific limitation on “elements with some electrical action” as long as it can transmit electrical signals between constituent elements that are connected. Examples of “elements with some electrical action” include not only electrodes and wiring but also switching elements such as transistors, resistors, inductors, capacitors, and other elements with one or more functions.

In the description, a transistor refers to an element with at least three terminals, including a gate electrode (gate), a drain electrode, and a source electrode. The transistor has a channel region between the drain electrode (drain terminal, drain region, or drain) and the source electrode (source terminal, source region, or source), and current can flow through the drain electrode, channel region, and source electrode. In the disclosure, the channel region refers to the region through which the current primarily flows.

Furthermore, the gate electrode of the transistor can be referred to as the control electrode. In cases where the polarity of transistors is reversed or the direction of current changes in the operation of the circuit, the functions of the “source electrode” and “drain electrode” are sometimes interchanged. Therefore, in the description, the “source electrode” and “drain electrode” can be interchanged.

In the description, “parallel” refers to a state where the angle formed by two straight lines is above −10° and below 10°, so it can include a state where the angle is above −5° and below 5°. Additionally, “vertical” refers to a state where the angle formed by two straight lines is above 80° and below 100°, so it can include a state where the angle is above 85° and below 95°.

In the description, triangles, rectangles, trapezoids, pentagons, or hexagons, etc., are not strictly defined and can be approximate triangles, rectangles, trapezoids, pentagons, or hexagons, etc. Small deformations caused by tolerances can exist, and there may be features such as chamfers, curved edges, and deformations.

In the description, “film” and “layer” can be interchangeable. For example, “conductive layer” can sometimes be replaced with “conductive film.” Similarly, “insulation film” can sometimes be replaced with “insulation layer”.

To keep the following description of embodiments of the disclosure clear and concise, detailed descriptions of known functions and known components have been omitted.

High-resolution products, such as 8K and 16K display products, are the main focus for future products. However, current 8K vertical alignment (VA) liquid crystal products face challenges of low transmittance and poor color shift.

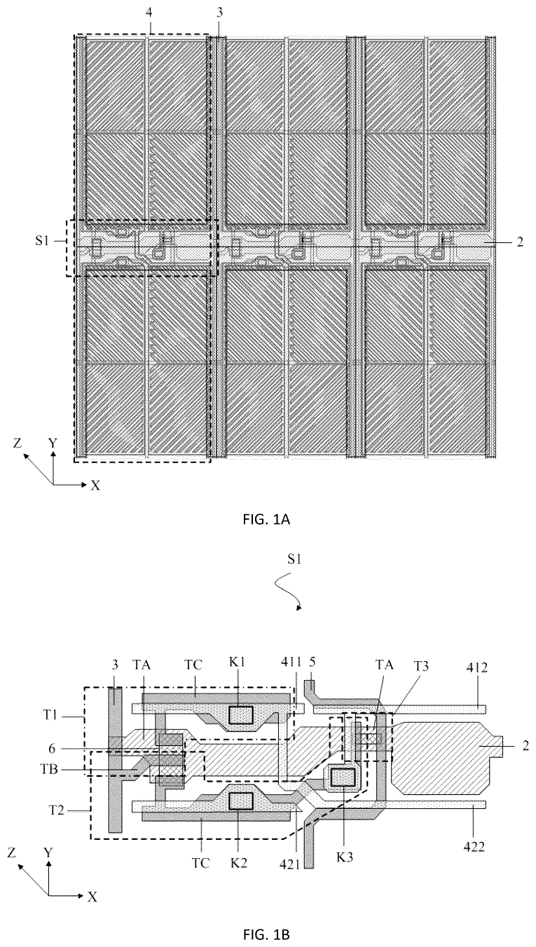

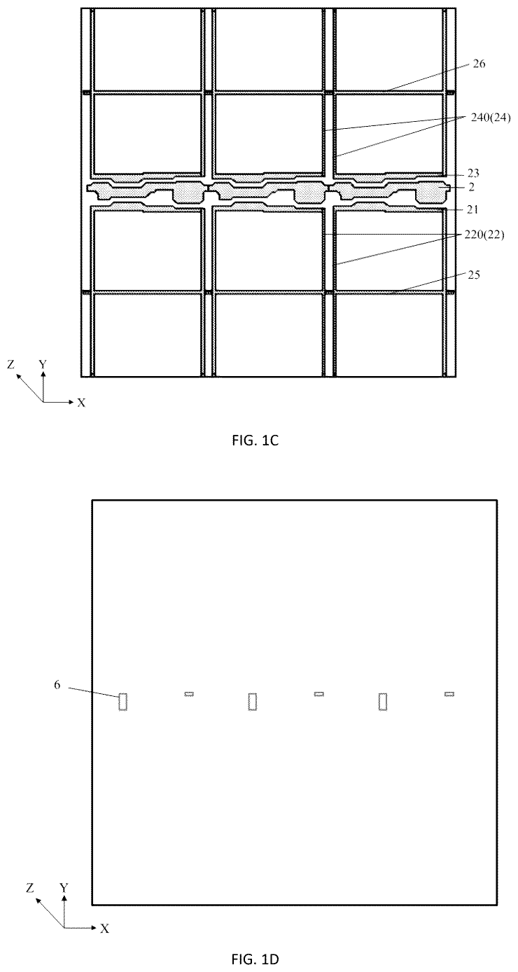

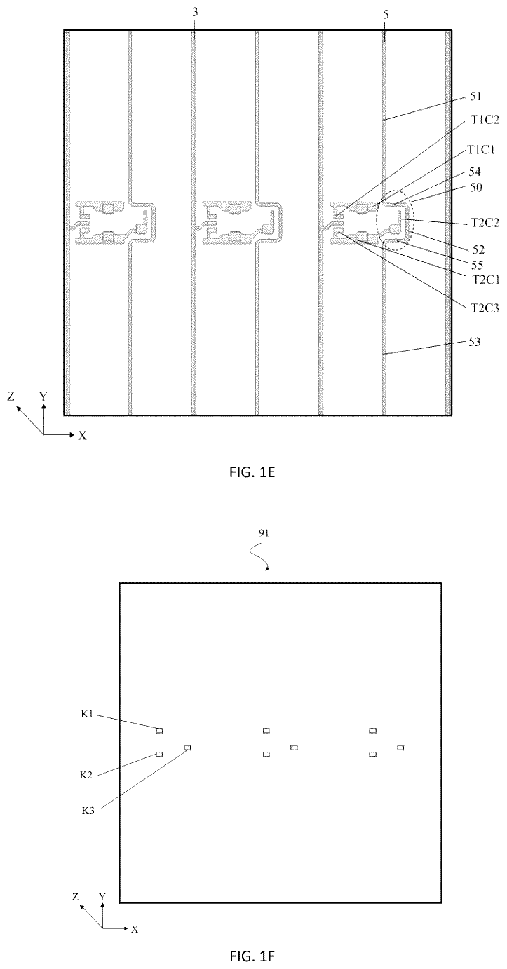

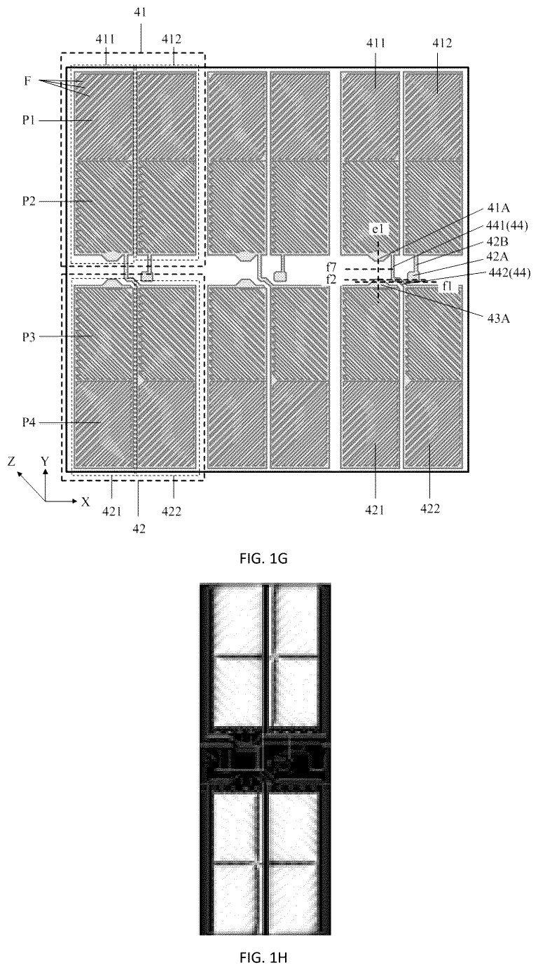

In view of this, referring to FIGS. 1A-1G, FIGS. 2A-2G, FIGS. 3A-3G, FIGS. 4A-4G, FIGS. 5A-5G, and FIGS. 6A-6G, embodiments of the disclosure provide an array substrate including:
a base 1;
a plurality of gate lines 2 disposed at a side of the base 1 and extending along a first direction X;
a plurality of data lines 3 extending along a second direction Y; specifically, the second direction Y may intersect with the first direction X; specifically, the second direction Y may be perpendicular to the first direction X; specifically, the second direction Y may be a direction of a pixel electrode column, and the first direction X may be a direction of a pixel electrode row; and
a plurality of pixel electrodes 4, where the pixel electrode 4 includes: a first pixel electrode 41 located at a side of the gate line 2 and a second pixel electrode 42 located at the other side of the gate line 2. The first pixel electrode 41 includes: a first sub-pixel electrode 411 and a second sub-pixel electrode 412 arranged along the first direction X. The second pixel electrode 42 includes: a third sub-pixel electrode 421 and a fourth sub-pixel electrode 422 arranged along the first direction X. Specifically, for example, as shown in FIG. 1G, the pixel electrode 4 includes the first pixel electrode 41 above the gate line 2 and the second pixel electrode 42 below the gate line 2. The first pixel electrode 41 includes the first sub-pixel electrode 411 on the left side and the second sub-pixel electrode 412 on the right side. The second pixel electrode 42 includes the third sub-pixel electrode 421 on the left side and the fourth sub-pixel electrode 422 on the right side.

One of the first sub-pixel electrode 411 or the second sub-pixel electrode 412 is electrically connected with one of the third sub-pixel electrode 421 or the fourth sub-pixel electrode 422. The brightness of the two connected electrically as an integration is different from the brightness of the other two connected electrically. Specifically, for example, the first sub-pixel electrode 411 can be electrically connected with the third sub-pixel electrode 421, and the second sub-pixel electrode 412 can be electrically connected with the fourth sub-pixel electrode 422; or the first sub-pixel electrode 411 can be electrically connected with the fourth sub-pixel electrode 422, and the second sub-pixel electrode 412 can be electrically connected with the third sub-pixel electrode 421.

In the embodiments of the disclosure, the pixel electrode 4 includes the first pixel electrode 41 located at a side of the gate line 2 and the second pixel electrode 42 located at the other side of the gate line 2. The first pixel electrode 41 includes the first sub-pixel electrode 411 and the second sub-pixel electrode 412 arranged along the first direction X, and the second pixel electrode 42 includes the third sub-pixel electrode 421 and the fourth sub-pixel electrode 422 arranged along the first direction X. One of the first sub-pixel electrode 411 or the second sub-pixel electrode 412 is electrically connected with one of the third sub-pixel electrode 421 or the fourth sub-pixel electrode 422. That is, a pixel electrode 4 is divided into two parts, i.e., upper and lower parts, and the upper half of the pixel electrode is further divided into left and right parts, and the lower half of the pixel electrode is also divided into left and right parts. The brightness of the two connected electrically as an integration is different from the brightness of the other two connected electrically. An 8-domain distribution can be formed in one sub-pixel, and compared to a conventional 8-domain structure, the array substrate provided in the embodiments of the disclosure has fewer dark fringes and better transmittance, and can compensate for each other's viewing angles, improving the color shift between left and right viewing angles.

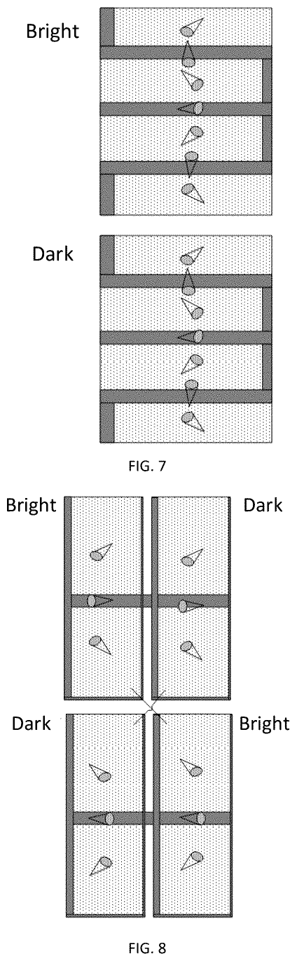

Specifically, as shown in FIGS. 7 and 8, FIG. 7 shows dark fringes in a conventional 8-domain structure, where numerous dark fringes are distributed, significantly affecting the transmittance. FIG. 8 shows the dark fringes of the array substrate provided in the embodiments of the disclosure, where the number of dark fringes is significantly reduced. In comparison, the 8-domain structure of the array substrate provided in embodiments of the disclosure has a significant advantage in improving transmittance. Moreover, the 8-domain structure shown in FIG. 7 does not have a good liquid crystal angle to compensate for left and right viewing angles; and all the horizontal liquid crystals are oriented to the right, and there are no horizontal liquid crystals that are oriented to the left. However, the array substrate provided in the embodiments of the disclosure, as shown in FIG. 8, allows mutual compensation for the horizontal liquid crystals that are oriented to the left and the horizontal liquid crystals that are oriented to the right in terms of viewing angles, thereby improving the color shift between left and right viewing angles.

Combining FIGS. 1A, 1G, and 8, in one pixel electrode 4, the first pixel electrode 41 has “ [symbol] ”-shaped slits, and the second pixel electrode 42 has reverse “ [symbol] ”-shaped slits. In conjunction with the extension directions of the slits F, the first pixel electrode 41 can have two liquid crystal alignment directions, which can be 225° and 135° respectively; and the second pixel electrode 42 can have two liquid crystal alignment directions, which can be 315° and 45°. In cooperation with bright and dark areas based on left-right division, an alignment mode of 8 domains in one sub-pixel can be formed when using a specific UV photo alignment (SUVA) technology.

It should be noted that, in the embodiments of the disclosure, one of the first sub-pixel electrode 411 or the second sub-pixel electrode 412 can be electrically connected with one of the third sub-pixel electrode 421 or the fourth sub-pixel electrode 422 in such a way that: one of the first sub-pixel electrode 411 or the second sub-pixel electrode 412 is electrically connected with one of the third sub-pixel electrode 421 or the fourth sub-pixel electrode 422 in the layer of the pixel electrode 4, while the other two are electrically connected not in the layer of the pixel electrode 4 but via other structures, for example, the other two both are electrically connected with a drain electrode of the same transistor. Specifically, for example, the first sub-pixel electrode 411 is electrically connected with the third sub-pixel electrode 421 in the layer of the pixel electrode 4, presenting one brightness; and the second sub-pixel electrode 412 is not electrically connected with the third sub-pixel electrode 421 in the layer of the pixel electrode 4, but both can be electrically connected with the drain electrode of the same transistor (i.e., electrically connected through the layer of the drain electrode), presenting another brightness. The brightness of the two electrically connected in the layer of the pixel electrode 4 is different from the brightness of the other two not electrically connected in the layer of the pixel electrode 4.

The expression of “one brightness of the two connected electrically as an integration is different from another brightness of the other two connected electrically” refers to the comparison of brightness within one sub-pixel when the display panel is powered and lighted up.

In a possible embodiment, combining FIGS. 1A-1G, FIGS. 2A-2G, FIGS. 3A-3G, FIGS. 4A-4G, FIGS. 5A-5G, and FIGS. 6A-6G, the array substrate further includes a plurality of transistors T. Multiple transistors electrically connected with the same pixel electrode 4 are all electrically connected with the same data line 3 and the same gate line 2. For example, as shown in FIG. 1B, three transistors electrically connected with the same pixel electrode 4, namely a first transistor T1, a second transistor T2, and a third transistor T3, are electrically connected with the same data line 3 and the same gate line 2. The second sub-pixel electrode 412 is located at the side of the first sub-pixel electrode 411 away from the data line 3 in electrically connection, and the fourth sub-pixel electrode 422 is located at the side of the third sub-pixel electrode 421 away from the data line 3 in electrically connection. The first sub-pixel electrode 411 is electrically connected with the fourth sub-pixel electrode 422. Specifically, the first sub-pixel electrode 411 and the fourth sub-pixel electrode 422 are electrically connected in the layer of the pixel electrode 4, and the second sub-pixel electrode 412 and the third sub-pixel electrode 421 are electrically connected with a second electrode TC of the second transistor T2. In the embodiments of the disclosure, the first sub-pixel electrode 411 and the fourth sub-pixel electrode 422 are electrically connected in the layer of the pixel electrode 4, and the second sub-pixel electrode 412 and the third sub-pixel electrode 421 are electrically connected, that is, four parts of the electrode 4 are electrically cross-connected in pairs, facilitating an 8-domain distribution in the same pixel electrode 4.

It should be noted that multiple transistors electrically connected with the same pixel electrode 4 can be in direct or indirect electrical connection with the same pixel electrode 4. For example, the first transistor T1 and the second transistor T2 can be electrically connected with the pixel electrode 4 directly, and the third transistor T3 can be considered electrically connected with the pixel electrode 4 because it is electrically connected with the second transistor T2. Specifically, multiple transistors electrically connected with the same pixel electrode 4 can be transistors driving the same pixel electrode 4.

In a possible embodiment, combining FIG. 1A-1G, the array substrate further includes a first signal line 5 extending along the second direction Y. The multiple transistors T include a first transistor T1, a second transistor T2, and a third transistor T3.

A control electrode TA of the first transistor T1 is electrically connected with the gate line 2, a first electrode TB of the first transistor T1 is electrically connected with the data line 3, and a second electrode TC of the first transistor T1 is electrically connected with the first sub-pixel electrode 411 and the fourth sub-pixel electrode 422. Specifically, the second electrode TC of the first transistor T1 can be electrically connected with the first sub-pixel electrode 411 and the fourth sub-pixel electrode 422 through a first via hole K1.

A control electrode TA of the second transistor T2 is electrically connected with the gate line 2, a first electrode TB of the second transistor T2 is electrically connected with the data line 3, and a second electrode TC of the second transistor T2 is electrically connected with the second sub-pixel electrode 412 and the third sub-pixel electrode 421. Specifically, the second electrode TC of the second transistor T2 can be electrically connected with the third sub-pixel electrode 421 through the second via hole K2. The second electrode TC of the second transistor T2 can be electrically connected with the second sub-pixel electrode 412 through the third via hole K3.

A control electrode TA of the third transistor T3 is electrically connected with the gate line 2, a first electrode TB of the third transistor T3 shares the second electrode TC of the second transistor T2, and a second electrode TC of the third transistor T3 shares the first signal line 5.

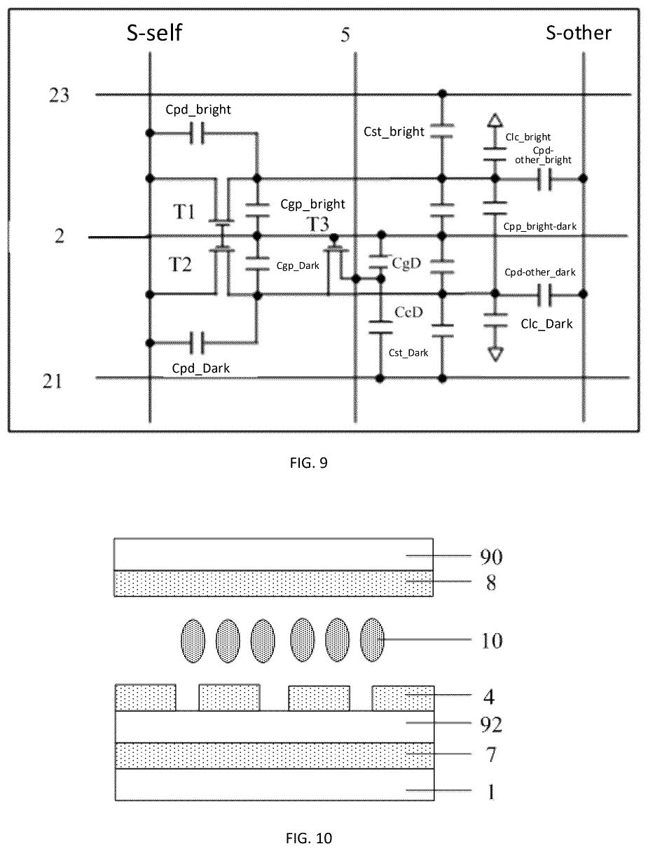

FIG. 9 can be an equivalent circuit diagram corresponding to FIG. 1B, where S-self indicates a data line at the left side of the pixel, i.e., the signal line that transmits data signals for the current sub-pixel and the data line electrically connected with the current sub-pixel; and S-other indicates a data line at the right side of the pixel, which is also the data line for the horizontally adjacent pixel. The pixel circuit may include a first transistor T1, a second transistor T2, a third transistor T3, a first capacitor Cpd_bright, a second capacitor Cgp_bright, a third capacitor Cst_bright, a fourth capacitor Clc_bright, a fifth capacitor Cpp_bright-dark, a sixth capacitor Cpd-other_bright, a seventh capacitor Cpd_dark, an eighth capacitor Cgp_dark, a ninth capacitor Cst_dark, a tenth capacitor Clc_dark, an eleventh capacitor Cpd-other_dark, a twelfth capacitor CgD, and a thirteenth capacitor CcD. The first capacitor Cpd_bright can be formed between the first pixel electrode 41 and the data line 3. The second capacitor Cgp_bright can be formed between the first pixel electrode 41 and the gate line 2. The third capacitor Cst_bright can be formed by an overlapping area between the first pixel electrode 41 and a third common line 23. The fourth capacitor Clc_bright can be formed by the first pixel electrode 41 and a common electrode on the counter substrate. The fifth capacitor Cpp_bright-dark can be formed between the first pixel electrode 41 and the second pixel electrode 42. The sixth capacitor Cpd-other_bright can be formed between the first pixel electrode 41 and an adjacent data line 3. The seventh capacitor Cpd_dark can be formed between the second pixel electrode 42 and the data line 3. The eighth capacitor Cgp_dark can be formed between the second pixel electrode 42 and the gate line 2. The ninth capacitor Cst_dark can be formed by an overlapping area between the second pixel electrode 42 and a first common line 21. The tenth capacitor Clc_dark can be formed between the second pixel electrode 42 and the common electrode on the counter substrate. The eleventh capacitor Cpd-other_dark can be formed between the second pixel electrode 42 and the adjacent data line 3. The twelfth capacitor CgD can be formed by an overlapping area between the gate line 2 and the first signal line 5. The thirteenth capacitor CcD can be formed by an overlapping area between the first signal line 5 and the first common line 21.

Specifically, as shown in FIGS. 1A and 9, since the third transistor T3 is connected with the second transistor T2, a voltage applied to the second sub-pixel electrode 412 and the third sub-pixel electrode 421 will be provided partially to the twelfth capacitor CgD (and/or, the thirteenth capacitor CcD, and/or, the first signal line 5) through the third transistor T3, making the voltage at the second sub-pixel electrode 412 and the third sub-pixel electrode 421 lower than the voltage at the first sub-pixel electrode 411 and the fourth sub-pixel electrode 422.

Consequently, the brightness of the second sub-pixel electrode 412 and the third sub-pixel electrode 421 is smaller than the brightness of the first sub-pixel electrode 411 and the fourth sub-pixel electrode 422, thereby forming a display effect with different brightness in the sub-pixel.

In a possible embodiment, a voltage applied to the first signal line 5 can be consistent with a voltage applied to the common electrode layer on the counter substrate, i.e., the common voltage may be applied.

In a possible embodiment, in combination with FIG. 1A-1G, the pixel electrode 4 further includes a first sub-pixel electrode convex portion 41A connected with a side of the first sub-pixel electrode 411 facing the third sub-pixel electrode 421; and the second electrode TC of the first transistor T1 is electrically connected with the first sub-pixel electrode 411 through the first sub-pixel electrode convex portion 41A. In the embodiments of the disclosure, the first sub-pixel electrode 411 is further provided with the first sub-pixel electrode convex portion 41A at the side facing the third sub-pixel electrode 421, which allows the simple and neat wiring when connecting with the second electrode TC of the first transistor T1, and is conducive to concise wiring of the gap between the first pixel electrode 41 and the second pixel electrode 42, avoiding the risk of short circuits during patterning and etching when the layout for multiple patterns is complicated.

In a possible embodiment, in combination with FIG. 1A-1G, the pixel electrode 4 further includes a connection portion 44 connecting the first sub-pixel electrode 411 and the fourth sub-pixel electrode 422. The connection portion 44 includes a first connecting portion 441 extending along the second direction Y and a second connecting portion 442 extending along a third direction Z. One end of the first connecting portion 441 is electrically connected with one end of the first sub-pixel electrode 411 facing the third sub-pixel electrode 421, and the other end of the first connecting portion 441 is electrically connected with one end of the second connecting portion 442. The other end of the second connecting portion 442 is electrically connected with one end of the fourth sub-pixel electrode 422 facing the second sub-pixel electrode 412.

In the embodiments of the disclosure, the first sub-pixel electrode 411 and the fourth sub-pixel electrode 422 are directly electrically connected in the layer of the pixel electrode 4 through the connection portion 44. The connection portion 44 includes the first connecting portion 441 extending along the second direction Y and the second connecting portion 442 extending along the third direction Z. The wiring of the connection portion 44 is simple and structured, which is conducive to concise wiring of the gap between the first pixel electrode 41 and the second pixel electrode 42, avoiding the risk of short circuits during patterned etching when the layout of multiple patterns is complicated.

In a possible embodiment, the third direction Z intersects with the first direction X and intersects with the second direction Y. An angle formed between the third direction Z and the second direction Y can range from 0 to 90°. Specifically, the angle formed between the third direction Z and the second direction Y can range from 30° to 60°. Specifically, the angle formed between the third direction Z and the second direction Y can be 45°.

In a possible embodiment, in combination with FIG. 1A-1G, the pixel electrode 4 further includes a third sub-pixel electrode convex portion 43A connected with a side of the third sub-pixel electrode 421 facing the first sub-pixel electrode 411; and the second electrode TC of the second transistor T2 is electrically connected with the third sub-pixel electrode 421 through the third sub-pixel electrode convex portion 43A. In the embodiments of the disclosure, the third sub-pixel electrode 421 is further provided with the third sub-pixel electrode convex portion 43A at the side facing the first sub-pixel electrode 411, and the wiring is simple and structured when connecting with the second electrode TC of the second transistor T2, which is conducive to concise wiring of the gap between the first pixel electrode 41 and the second pixel electrode 42, avoiding the risk of short circuits during the patterned etching when the layout for multiple patterns is complicated.

In a possible embodiment, as shown in FIGS. 1A-1G, the pixel electrode 4 further includes: a second sub-pixel electrode extension portion 42B extending along the second direction Y, and a second sub-pixel electrode convex portion 42A. One end of the second sub-pixel electrode extension portion 42B is electrically connected with one end of the second sub-pixel electrode 412 facing the fourth sub-pixel electrode 422, and the other end of the second sub-pixel electrode extension portion 42B is electrically connected with the second sub-pixel electrode convex portion 42A. The second electrode TC of the second transistor T2 is electrically connected with the second sub-pixel electrode 412 through the second sub-pixel electrode convex portion 42A. In the embodiments of the disclosure, at the side of the second sub-pixel electrode 412 facing the fourth sub-pixel electrode 422, the second sub-pixel electrode extension portion 42B extending along the second direction Y and the second sub-pixel electrode convex portion 42A are further provided, which is conducive to the electrical connection of both the second sub-pixel electrode 412 and the third sub-pixel electrode 421 to the second electrode TC of the second transistor T2. In addition, the wiring layout for the connection between the second sub-pixel electrode 412 and the second electrode TC of the second transistor T2 is simple and structured, facilitating a concise wiring of the gap between the first pixel electrode 41 and the second pixel electrode 42, thereby avoiding the risk of short circuits during patterned etching when the layout for multiple patterns is complicated.

In a possible embodiment, as shown in FIGS. 1A-1G, an extension direction of the second sub-pixel electrode extension portion 42B is parallel to an extension direction of the first connecting portion 441, which is advantageous for a concise wiring of the gap between the first pixel electrode 41 and the second pixel electrode 42, thereby avoiding the risk of short circuits during patterned etching when the layout for multiple patterns is complicated.

In a possible embodiment, as shown in FIGS. 1A-1G, the second sub-pixel electrode convex portion 42A has an outer edge f1 extending along the first direction X and located at the side away from the second sub-pixel electrode 412. The third sub-pixel electrode convex portion 43A has an outer edge f2 extending along the first direction X and located at the side away from the third sub-pixel electrode 421.

An extension line of the outer edge f1 of the second sub-pixel electrode convex portion coincides with an extension line of the outer edge f2 of the third sub-pixel electrode convex portion; or, the extension line of the outer edge f1 of the second sub-pixel electrode convex portion at least partially overlaps with the third sub-pixel electrode convex portion 43A; or, the extension line of the outer edge f2 of the third sub-pixel electrode convex portion at least partially overlaps with the second sub-pixel electrode convex portion 42A. This arrangement is advantageous for the electrical connection of both the second sub-pixel electrode 412 and the third sub-pixel electrode 421 to the second electrode TC of the second transistor T2, allowing a concise wiring of the gap between the first pixel electrode 41 and the second pixel electrode 42 and avoiding the risk of short circuits during the patterned etching when the layout for multiple patterns is complicated.

In a possible embodiment, as shown in FIGS. 1A-1G, a line e1 connecting a center of the third sub-pixel electrode convex portion 43A and a center of the first sub-pixel electrode convex portion 41A is parallel to the second direction Y. This arrangement is advantageous for a simplified pattern of the gap between the first pixel electrode 41 and the second pixel electrode 42, avoiding the risk of short circuits during the patterned etching when the layout for multiple patterns is complicated.

In a possible embodiment, as shown in FIGS. 1A-1G, the third sub-pixel electrode convex portion 43A and the first sub-pixel electrode convex portion 41A can be symmetrical about a first axis line f7 located between the first pixel electrode 41 and the second pixel electrode 42 and extending along the first direction X.

In a possible embodiment, as shown in FIGS. 1A-1G, a shape of an orthographic projection of the first sub-pixel electrode convex portion 41A on the base 1 can be a trapezoid, and a shape of an orthographic projection of the third sub-pixel electrode convex portion 43A on the base 1 can be a trapezoid. In a possible embodiment, the shape of the orthographic projection of the first sub-pixel electrode convex portion 41A on the base 1 can also be a rectangle, semi-circle, or semi-ellipse; and the shape of the orthographic projection of the third sub-pixel electrode convex portion 43A on the base 1 can also be a rectangle, semi-circle, or semi-ellipse.

In a possible embodiment, as shown in FIGS. 1A-1G, the second electrode TC of the first transistor T1 includes: a first portion T1C1 extending along the first direction X. An orthographic projection of the first portion T1C1 of the first transistor T1 on the base 1 has an overlapping region with an orthographic projection of the first sub-pixel electrode convex portion 41A. This facilitates the electrical connection between the first portion T1C1 of the first transistor T1 and the first sub-pixel electrode convex portion 41A through the first via hole K1.

In a possible embodiment, as shown in FIGS. 1A-1G, the second electrode TC of the first transistor T1 includes: a second portion T1C2 extending along the second direction Y and electrically connected with the first portion T1C1 of the first transistor. Specifically, an orthographic projection of the second portion T1C2 of the first transistor on the base 1 has an overlapping region with an orthographic projection of the active pattern 6 on the base 1.

In a possible embodiment, as shown in FIGS. 1A-1G, the second electrode TC of the second transistor T2 includes: a first portion T2C1 extending along the first direction X, and a second portion T2C2 extending along the second direction Y and electrically connected with an end of the first portion T2C1 of the second transistor. An orthographic projection of the first portion T2C1 of the second transistor on the base 1 has an overlapping area with an orthographic projection of the third sub-pixel electrode convex portion 43A, which facilitates the electrical connection between the first portion T2C1 of the second transistor and the third sub-pixel electrode convex portion 43A through the second via hole K2. An orthographic projection of the second portion T2C2 of the second transistor on the base 1 has an overlapping area with an orthographic projection of the second sub-pixel electrode convex portion 42A on the base 1, which facilitates the electrical connection between the second portion T2C2 of the second transistor and the second sub-pixel electrode convex portion 42A through the third via hole K3.

In a possible embodiment, as shown in FIGS. 1A-1G, the second electrode TC of the second transistor T2 includes: a third portion T2C3 extending along the second direction Y and electrically connected with the other end of the first portion T2C1 of the second transistor.

Specifically, an orthographic projection of the third portion T2C3 of the second transistor on the base 1 has an overlapping region with an orthographic projection of the active pattern 6 on the base 1.

In a possible embodiment, as shown in FIGS. 1A-1G, at least part of the orthographic projection of the second portion T2C2 of the second transistor on the base 1 overlaps with at least part of the orthographic projection of the second sub-pixel electrode extension portion 42B on the base 1. Since the second portion T2C2 of the second transistor and the gate line 2 have an overlapping region, a coupling capacitor is formed between them. The second sub-pixel electrode extension portion 42B covers a part of the second portion T2C2 of the second transistor, which can shield a coupling capacitor between a part of the second portion T2C2 of the second transistor and the gate line 2. Moreover, at least part of the orthographic projection of the second portion T2C2 of the second transistor on the base 1 overlaps with at least part of the orthographic projection of the second sub-pixel electrode extension portion 42B on the base 1, which makes the wiring of the array substrate easy, reduces wiring width, and optimizes the wiring layout.

In a possible embodiment, the orthographic projection of the second portion T2C2 of the second transistor on the base 1 can have no overlapping with the orthographic projection of the second sub-pixel electrode extension portion 42B on the base 1.

In a possible embodiment, as shown in FIGS. 1A to 1G, the first signal line 5 has a recessed portion 50. At least part of the orthographic projection of the second portion T2C2 of the second transistor on the base 1 is located in a region surrounded by an orthographic projection of the recessed portion 50 on the base 1. In the embodiments of the disclosure, the first signal line 5 has the recessed portion 50, and thus the first signal line 5 can avoid the second portion T2C2 of the second transistor while arranging the first signal line 5 in the same layer as the second electrode TC of the second transistor T2, preventing short circuits between the first signal line 5 and the second electrode of the second transistor T2.

In a possible embodiment, as shown in FIGS. 1A to 1G, the first signal line 5 includes: a first signal portion 51, a second signal portion 52, and a third signal portion 53 that are sequentially arranged along the second direction Y; a fourth signal portion 54 extending along the first direction X and connecting the second signal portion 52 and the first signal portion 51; and a fifth signal portion 55 extending along the first direction X and connecting the second signal portion 52 and the third signal portion 53. An extension line of the first signal portion 51 coincides with an extension line of the third signal portion 53, and an extension line of the second signal portion 52 does not coincide with the extension line of the first signal portion 51. The second signal portion 52, the fourth signal portion 54, and the fifth signal portion 55 together form the recessed portion 50. The fourth signal portion 54 and/or the fifth signal portion 55 at least partially overlap(s) with the pixel electrode 4.

Specifically, the third signal portion 53 can serve as the second electrode TC of the third transistor T3. In this way, a part of the voltage on the first sub-pixel electrode 411 and the fourth sub-pixel electrode 422 can be released to the first signal line 5 via the third transistor T3.

In a possible embodiment, as shown in FIGS. 1A to 1G, the first signal line 5 is in the same layer as the data line 3. In this way, the first signal line 5 can be formed while the data line 3 is formed, which simplifies the production process of the array substrate and reduces the production cost of the array substrate while achieving the display effect of different brightness in the same sub-pixel.

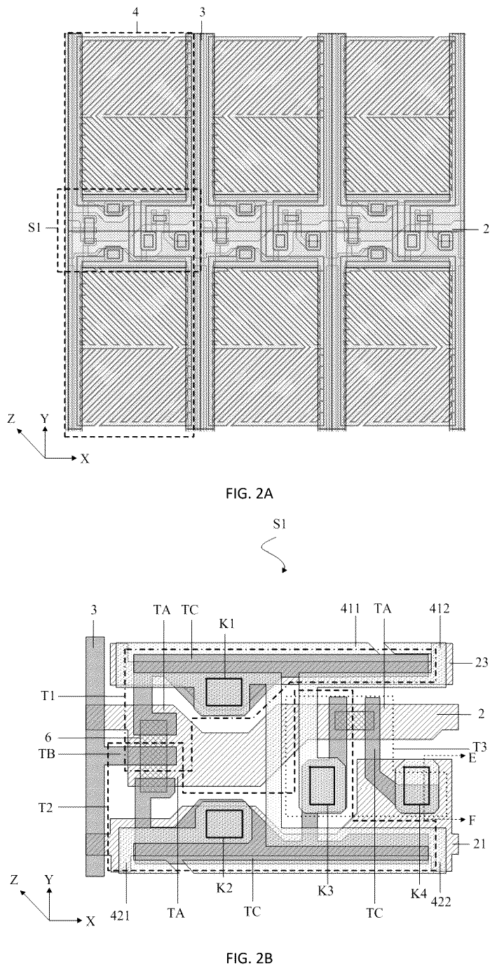

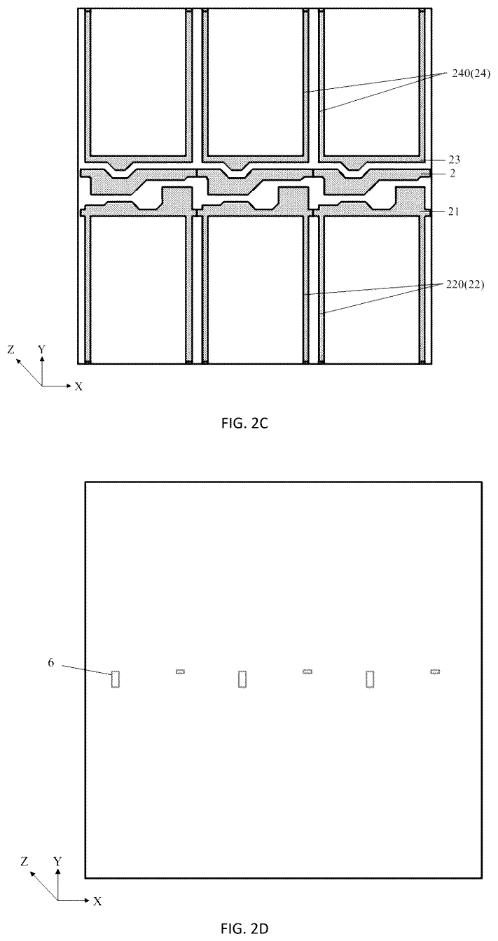

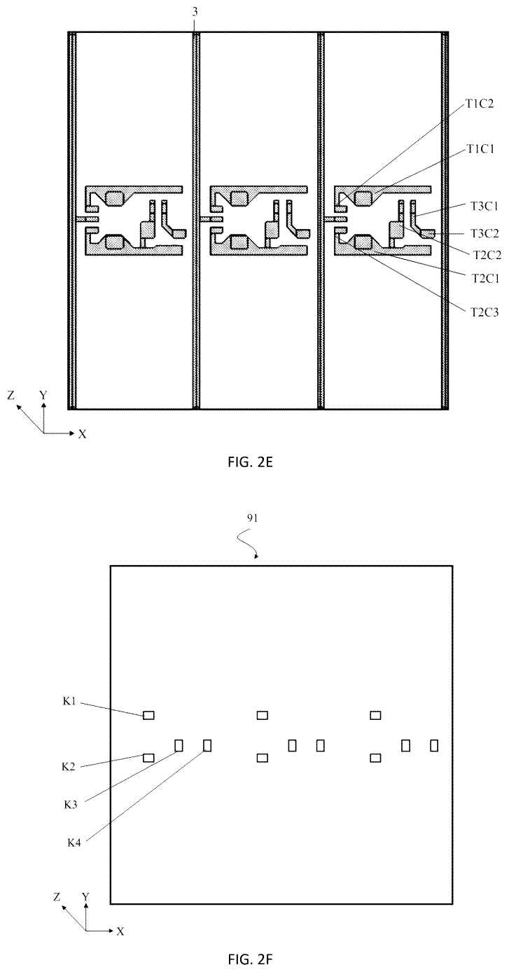

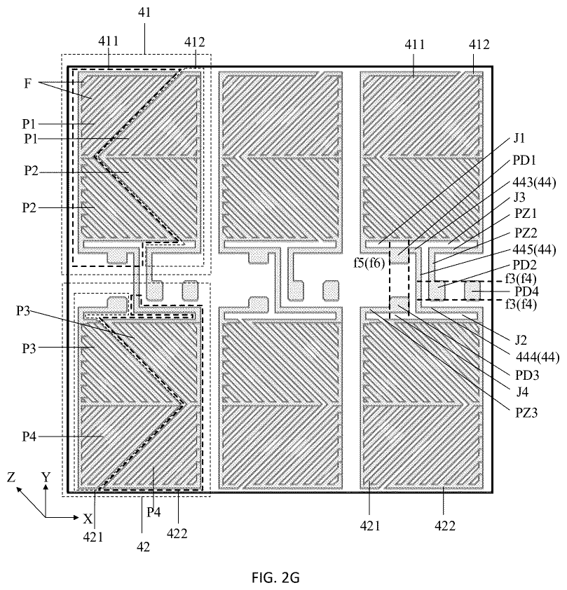

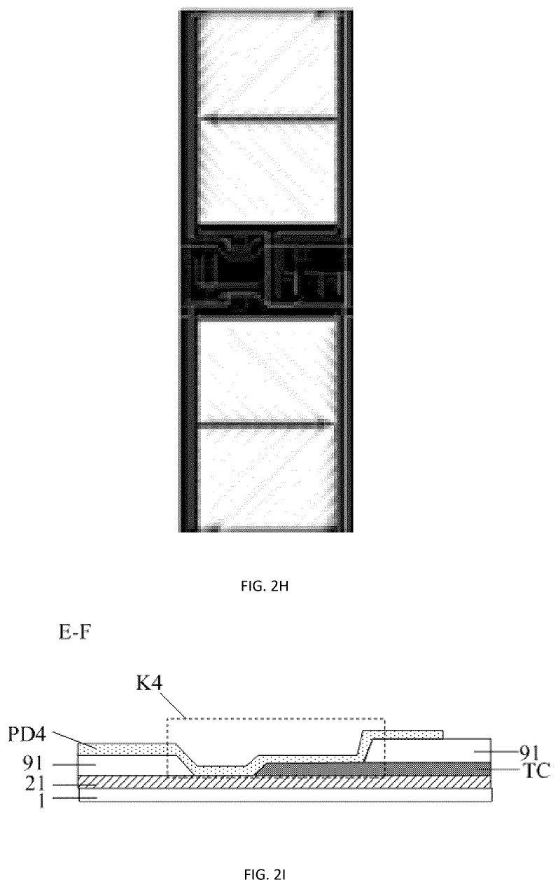

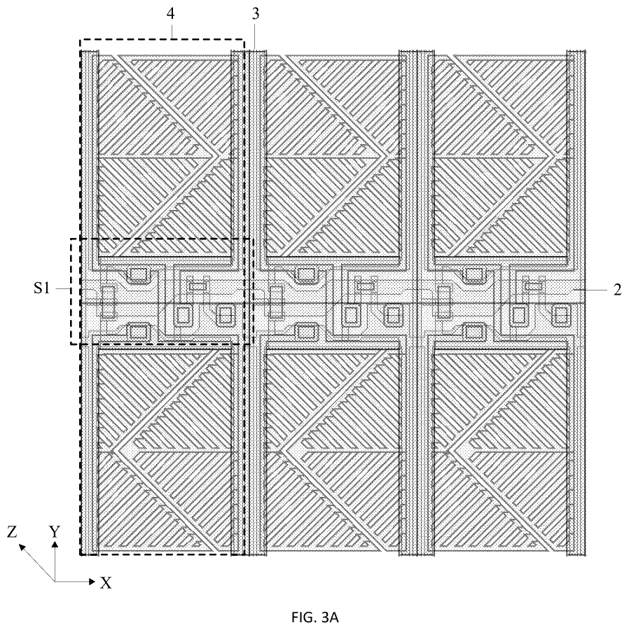

In a possible embodiment, as shown in FIGS. 2A to 2G, FIGS. 3A to 3G, FIGS. 4A to 4G, and FIGS. 5A to 5G, the array substrate further includes: a first common line 21 located at a side of the gate line 2 and extending along the first direction X. The multiple transistors T includes: a first transistor T1, a second transistor T2, and a third transistor T3 electrically connected with the data line 3.

The control electrode TA of the first transistor T1 is electrically connected with the gate line 2, the first electrode TB of the first transistor T1 is electrically connected with the data line 3, and the second electrode TC of the first transistor T1 is electrically connected with the first sub-pixel electrode 411 and the fourth sub-pixel electrode 422. Specifically, the second electrode TC of the first transistor T1 can be electrically connected with the first sub-pixel electrode 411 and the fourth sub-pixel electrode 422 through the first via hole K1.

The control electrode TA of the second transistor T2 is electrically connected with the gate line 2, the first electrode TB of the second transistor T2 is electrically connected with the data line 3, and the second electrode TC of the second transistor T2 is electrically connected with the second sub-pixel electrode 412 and the third sub-pixel electrode 421. Specifically, the second electrode TC of the second transistor T2 can be electrically connected with the third sub-pixel electrode 421 through the second via hole K2, and the second electrode TC of the second transistor T2 can be electrically connected with the second sub-pixel electrode 412 through the third via hole K3.

The control electrode TA of the third transistor T3 is electrically connected with the gate line 2, the first electrode TB of the third transistor T3 shares the second electrode TC of the second transistor T2, and the second electrode TC of the third transistor T3 is electrically connected with the first common line 21.

In the embodiments of the disclosure, since the third transistor T3 is connected with the second transistor T2, a voltage applied to the second sub-pixel electrode 412 and the third sub-pixel electrode 421 will be partially divided to the first common line 21 through the third transistor T3, causing the voltage of the second sub-pixel electrode 412 and the third sub-pixel electrode 421 to be lower than the voltage of the first sub-pixel electrode 411 and the fourth sub-pixel electrode 422. As a result, the brightness of the second sub-pixel electrode 412 and the third sub-pixel electrode 421 is lower than the brightness of the first sub-pixel electrode 411 and the fourth sub-pixel electrode 422, forming the display effect of different brightness in the sub-pixel.

In a possible embodiment, as shown in FIGS. 2A to 2G, FIGS. 3A to 3G, FIGS. 4A to 4G, and FIGS. 5A to 5G, the pixel electrode 4 further includes: a connection portion 44 connecting the first sub-pixel electrode 411 and the fourth sub-pixel electrode 422, and a first lapping portion PD1 connected with the connection portion 44. The connection portion 44 includes: a third connecting portion 443 and a fourth connecting portion 444 extending along the first direction X, and a fifth connecting portion 445 extending along the second direction Y.

One end of the third connecting portion 443 is connected with the first sub-pixel electrode 411, one end of the fourth connecting portion 444 is connected with the fourth sub-pixel electrode 422, one end of the fifth connecting portion 445 is connected with the other end of the third connecting portion 443, and the other end of the fifth connecting portion 445 is connected with the other end of the fourth connecting portion 444. The first lapping portion PD1 is electrically connected with the third connecting portion 443 and is located at the side away from the connected first sub-pixel electrode 411.

The second electrode TC of the first transistor T1 is electrically connected with the first sub-pixel electrode 411 and the fourth sub-pixel electrode through the first lapping portion PD1.

In the embodiments of the disclosure, the connection portion 44 includes the third connecting portion 443 and the fourth connecting portion 444 extending along the first direction X, and the fifth connecting portion 445 extending along the second direction Y, making the wiring of the connection portion 44 regular, and facilitating a concise wiring of the gap between the first pixel electrode 41 and the second pixel electrode 42, and avoiding the risk of short circuits during the patterned etching when the layout for multiple patterns is complicated. Further, the connection portion 44 is further connected with the first lapping portion PD1, facilitating the electrical connection of the first lapping portion PD1 to the second electrode TC of the first transistor T1 through the first via hole K1.

In a possible embodiment, as shown in FIGS. 2A to 2G, FIGS. 3A to 3G, FIGS. 4A to 4G, and FIGS. 5A to 5G, the pixel electrode further includes: a first transfer portion PZ1 extending along the first direction X, a second transfer portion PZ2 extending along the second direction Y, and a second lapping portion PD2. One end of the first transfer portion PZ1 is electrically connected with one end of the second sub-pixel electrode 412 facing the fourth sub-pixel electrode 422, and the other end of the first transfer portion PZ1 is electrically connected with one end of the second transfer portion PZ2; the other end of the second transfer portion PZ2 is electrically connected with the second lapping portion PD2; and the second electrode TC of the second transistor T2 is electrically connected with the second sub-pixel electrode 412 through the second lapping portion PD2. In the embodiments of the disclosure, a side of the second sub-pixel electrode 412 is provided with the first transfer portion PZ1, the second transfer portion PZ2 extending along the second direction Y, and the second lapping portion PD2. This allows the second sub-pixel electrode 412 to be electrically connected with the second electrode TC of the second transistor T2, and the wiring between the second sub-pixel electrode 412 and the second electrode TC of the second transistor T2 is simple and neat, facilitating the concise wiring of the gap between the first pixel electrode 41 and the second pixel electrode 42, and avoiding the risk of short circuits during the patterned etching when the layout for multiple patterns is complicated.

In a possible embodiment, as shown in FIGS. 2A to 2G, FIGS. 3A to 3G, FIGS. 4A to 4G, and FIGS. 5A to 5G, the extension direction of the second transfer portion PZ2 is parallel to the extension direction of the fifth connecting portion 445. This is beneficial for the concise wiring of the gap between the first pixel electrode 41 and the second pixel electrode 42, avoiding the risk of short circuits during the patterned etching when the layout for multiple patterns is complicated.

In a possible embodiment, as shown in FIGS. 2A to 2G, FIGS. 3A to 3G, FIGS. 4A to 4G, and FIGS. 5A to 5G, the extension line of the first transfer portion PZ1 coincides with the extension line of the third connecting portion 443. This is beneficial for the concise wiring of the gap between the first pixel electrode 41 and the second pixel electrode 42, avoiding the risk of short circuits during the patterned etching when the layout for multiple patterns is complicated.

In a possible embodiment, as shown in FIGS. 2A to 2G, FIGS. 3A to 3G, FIGS. 4A to 4G, and FIGS. 5A to 5G, the pixel electrode 4 further includes: a third transfer portion PZ3 extending along the first direction X, and a third lapping portion PD3. One end of the third transfer portion PZ3 is electrically connected with one end of the third sub-pixel electrode 421 facing the first sub-pixel electrode 411, and the other end of the third transfer portion PZ3 is electrically connected with the third lapping portion PD3; and the second electrode TC of the second transistor T2 is electrically connected with the third sub-pixel electrode 421 through the third lapping portion PD3. In the embodiments of the disclosure, a side of the third sub-pixel electrode 421 is provided with the third transfer portion PZ3 and the third lapping portion PD3. This allows the third sub-pixel electrode 421 to be electrically connected with the second electrode TC of the second transistor T2, and the wiring between the third sub-pixel electrode 421 and the second electrode TC of the second transistor T2 is simple and neat, facilitating the concise wiring of the gap between the first pixel electrode 41 and the second pixel electrode 42, and avoiding the risk of short circuits during the patterned etching when the layout for multiple patterns is complicated.

In a possible embodiment, as shown in FIGS. 2A to 2G, FIGS. 3A to 3G, FIGS. 4A to 4G, and FIGS. 5A to 5G, an extension line of the third transfer portion PZ3 coincides with the extension line of the fourth connecting portion 444. This is beneficial for the concise wiring of the gap between the first pixel electrode 41 and the second pixel electrode 42, and avoiding the risk of short circuits during the patterned etching when the layout for multiple patterns is complicated.

In a possible embodiment, as shown in FIGS. 2A-2G, 3A-3G, 4A-4G, and 5A-5G, a first gap J1 is provided between the third connecting portion 443 and the first pixel electrode 41; a second gap J2 is provided between the fourth connecting portion 444 and the second pixel electrode 42; a third gap J3 is provided between the first transfer portion PZ1 and the first pixel electrode 41; and a fourth gap J4 is provided between the third transfer portion PZ3 and the second pixel electrode 42. Specifically, as shown in FIG. 2G, the first sub-pixel electrode 411 and the fourth sub-pixel electrode 422 are brighter than the second sub-pixel electrode 412 and the third sub-pixel electrode 421. The first transfer portion PZ1 is a structure electrically connected with the darker second sub-pixel electrode 412 and has a lower applied voltage. A relative long opposing area is provided between the first transfer portion PZ1 and the first sub-pixel electrode 411 which has a larger applied voltage. By providing the third gap J3 between the first transfer portion PZ1 and the first sub-pixel electrode 411, problems such as breakdowns are avoided when they are close and have significantly different voltages. Similarly, the fourth gap J4 is provided between the third transfer portion PZ3 and the fourth sub-pixel electrode 422 to avoid problems such as breakdowns when they are close and have significantly different voltages. The first gap J1 between the third connecting portion 443 and the first pixel electrode 41 and the second gap J2 between the fourth connecting portion 444 and the second pixel electrode 42, can be formed to be relatively symmetrical with the third gap J3 and the fourth gap J4, which is advantageous for the neat and concise wiring between multiple patterns.

In a possible embodiment, as shown in FIGS. 2A-2G, 3A-3G, 4A-4G, and 5A-5G, the array substrate further includes: a fourth lapping portion PD4. The second electrode TC of the third transistor T3 is electrically connected with the first common line 21 through the fourth lapping portion PD4.

In a possible embodiment, as shown in FIGS. 2A-2G, 3A-3G, 4A-4G, and 5A-5G, the second electrode TC of the third transistor T3 can be electrically connected with the first common line 21 through the fourth via hole K4.

In a possible embodiment, as shown in FIG. 2I which may be a cross-sectional view along the dotted line EF in FIG. 2B, specifically, the fourth via hole K4 can be designed as a semi-via, partially exposing the first common line 21 and partially exposing the second electrode TC of the third transistor T3. The fourth lapping portion PD4 partially contacts the first common line 21 and partially contacts the second electrode TC of the third transistor T3 at the fourth via hole K4, achieving electrical connection between the first common line 21 and the second electrode TC of the third transistor T3 through the fourth lapping portion PD4. Specifically, the fourth via hole K4 is designed as a semi-via, allowing a step structure to be formed inside the fourth via hole K4 to drain the alignment liquid, thereby avoiding the occurrence of moiré patterns in the image.

In a possible embodiment, as shown in FIGS. 2A-2G, 3A-3G, 4A-4G, and 5A-5G, the fourth lapping portion PD4 has an outer edge f3 along the first direction X, the second lapping portion PD2 has an outer edge f4 extending along the first direction X, the first lapping portion PD1 has an outer edge f5 extending along the second direction Y, and the third lapping portion PD3 has an outer edge f6 extending along the second direction Y. An extension line of the outer edge f3 of the fourth lapping portion coincides with an extension line of the outer edge f4 of the second lapping portion; and an extension line of the outer edge f5 of the first lapping portion coincides with an extension line of the outer edge f6 of the third lapping portion.

In the embodiments of the disclosure, the extension line of the outer edge f3 of the fourth lapping portion coincides with the extension line of the outer edge f4 of the second lapping portion; and the extension line of the outer edge f5 of the first lapping portion coincides with the extension line of the outer edge f6 of the third lapping portion, resulting in a neat and concise wiring of the gap between the first pixel electrode 41 and the second pixel electrode 42, and avoiding the risk of short circuits during the patterned etching when the layout for multiple patterns is complicated.

In a possible embodiment, as shown in FIGS. 2A-2G, 3A-3G, 4A-4G, and 5A-5G, the second electrode TC of the first transistor T1 includes: the first portion T1C1 extending along the first direction X. An orthographic projection of the first portion T1C1 of the first transistor on the base 1 has an overlapping area with an orthographic projection of the first lapping portion PD1 on the base 1. This facilitates electrical connection between the first portion T1C1 of the first transistor and the first lapping portion PD1 through the first via hole K1.

In a possible embodiment, as shown in FIGS. 2A-2G, 3A-3G, 4A-4G, and 5A-5G, the second electrode TC of the first transistor T1 includes: a second portion T1C2 electrically connected with the first portion T1C1 of the first transistor and extending along the second direction Y. Specifically, an orthographic projection of the second portion T1C2 of the first transistor on the base 1 may have an overlapping area with an orthographic projection of the active pattern 6 on the base 1.

In a possible embodiment, as shown in FIGS. 2A-2G, 3A-3G, 4A-4G, and 5A-5G, the second electrode TC of the second transistor T2 includes: a first portion T2C1 extending along the first direction X, and a second portion T2C2 extending along the second direction Y and electrically connected with one end of the first portion T2C1 of the second transistor. An orthographic projection of the first portion T2C1 of the second transistor on the base 1 has an overlapping area with an orthographic projection of the third lapping portion PD3 on the base 1, thereby achieving electrical connection between the first portion T2C1 of the second transistor and the third lapping portion PD3 through the second via hole K2. An orthographic projection of the second portion T2C2 of the second transistor on the base has an overlapping area with an orthographic projection of the second lapping portion PD2 on the base 1, thereby achieving electrical connection between the second portion T2C2 of the second transistor and the second lapping portion PD2 through the third via hole K3.

In a possible embodiment, as shown in FIGS. 2A-2G, 3A-3G, 4A-4G, and 5A-5G, the second electrode TC of the second transistor T2 may further include: a third portion T2C3 extending along the second direction Y and electrically connected with the other end of the first portion T2C1 of the second transistor. Specifically, an orthographic projection of the third portion T2C3 of the second transistor on the base 1 may have an overlapping area with the orthographic projection of the active pattern 6 on the base 1.

In a possible embodiment, as shown in FIGS. 2A-2G, 3A-3G, 4A-4G, and 5A-5G, the second electrode TC of the third transistor T3 may include: a first portion T3C1 extending along the second direction Y, and a second portion T3C2 extending along the first direction X and connected with the first portion T3C1 of the third transistor.

In a possible embodiment, as shown in FIGS. 2A-2G, 3A-3G, 4A-4G, and 5A-5G, an extension direction of the first portion T3C1 of the third transistor is parallel to an extension direction of the second portion T2C2 of the second transistor.

In a possible embodiment, as shown in FIGS. 1A-1G, the array substrate further includes: a first common line 21 extending along the first direction and located at a side of the gate line 2. The first common line 21 is disconnected at an intersection with the data line 3. This avoids increasing the load on the data line 3 and affecting the signal transmission of the data line 3 due to overlap between the first common line 21 and the data line 3.

In a possible embodiment, as shown in FIGS. 1A-1G, 2A-2G, 3A-3G, 4A-4G, and 5A-5G, the array substrate further includes: a second common line group 22 connected with the first common line 21 and extending towards a side away from the gate line 2. The second common line group 22 includes two second common lines 220. The orthographic projection of the data line 3 on the base 1 has an overlapping area with an orthographic projection of a gap between the two second common lines 220 of the same second common line group 22 on the base 1.

Orthographic projections of the second common lines 220 on the base 1 are located at both sides of the orthographic projection of the data line 3, improving the coupling capacitance between the data line 3 and the second pixel electrode 42.

In a possible embodiment, as shown in FIGS. 1A-1G, 2A-2G, 3A-3G, 4A-4G, and 5A-5G, the array substrate further includes: a third common line 23 extending along the first direction X and located at the other side of the gate line 2, and a fourth common line group 24 connected with the third common line 23 and extending towards a side away from the gate line 2. The third common line 23 is disconnected at an intersection with the data line 3, which avoids increasing the load on the data line 3 and affecting the signal transmission of the data line 3 due to overlap between the third common line 23 and the data line 3. The fourth common line group 24 includes two fourth common lines 240. The orthographic projection of the data line 3 on the base 1 has an overlapping area with an orthographic projection of a gap between the two fourth common lines 240 of the same fourth common line group 24 on the base 1.

Orthographic projections of the fourth common lines 240 on the base 1 are located at both sides of the data line 3, improving the coupling capacitance between the data line 3 and the first pixel electrode 41.

In a possible embodiment, the first common line 21 and the third common line 23 can be electrically connected in a display area by bridging and punching a hole; or can be electrically connected in a non-display area. In a possible embodiment, the array substrate further includes the non-display area outside the display area. The non-display area may be provided with an annular common line surrounding the display area. The first common line 21 and the third common line 23 both can be electrically connected with the annular common line to have the same common voltage signal.

In a possible embodiment, as shown in FIGS. 1A-1G, the array substrate further includes: a fifth common line 25 extending along the first direction X and electrically connected with the second common lines 220. An orthographic projection of the fifth common line 25 on the base 1 passes through a central area of the orthographic projection of the second pixel electrode 42 on the base 1.

In a possible embodiment, as shown in FIGS. 1A-1G, the array substrate further includes: a sixth common line 26 extending along the first direction X and electrically connected with the fourth common lines 240. An orthographic projection of the sixth common line 26 on the base 1 passes through a central area of the orthographic projection of the first pixel electrode 41 on the base 1.

In a possible embodiment, as shown in FIGS. 1A-1G, 2A-2G, 3A-3G, 4A-4G, and 5A-5G, the first sub-pixel electrode 411 and the second sub-pixel electrode 412 each includes: a first sub-electrode portion P1 and a second sub-electrode portion P2 arranged along the second direction Y; and the third sub-pixel electrode 421 and the fourth sub-pixel electrode 422 each includes: a third sub-electrode portion P3 and a fourth sub-electrode portion P4 arranged along the second direction Y. The first sub-electrode portion P1, the second sub-electrode portion P2, the third sub-electrode portion P3, and the fourth sub-electrode portion P4 all has multiple slits F. Moreover, an extension direction of the slits F in the first sub-electrode portion P1 is the same as that in the fourth sub-electrode portion P4, and an extension direction of the slits F in the second sub-electrode portion P2 is the same as that in the third sub-electrode portion P3.

In a possible embodiment, a length of each of the slits F in a direction perpendicular to the extension direction can range from 2 μm to 4 μm. Specifically, a length of the slit F in the direction perpendicular to the extension direction can be 3 μm. In the embodiments of the disclosure, based on the array substrate provided in the embodiments of the disclosure, when the length of the slits F in the direction perpendicular to the extension direction is reduced to 3 μm, dark fringes are nearly eliminated.

Specifically, as shown in FIGS. 1A-1G, 2A-2G, 3A-3G, 4A-4G, and 5A-5G, an angle formed between the extension direction of the slits F in the first sub-electrode portion P1 and the first direction X can range from 40° to 50°, for example, it can be 45°; an angle formed between the extension direction of the slits F in the second sub-electrode portion P2 and the first direction X can range from 130° to 140°, for example, it can be 135°; an angle formed between the extension direction of the slits F in the third sub-electrode portion P3 and the first direction X can range from 130° to 140°, for example, it can be 135°; and an angle formed between the extension direction of the slits F in the fourth sub-electrode portion P4 and the first direction X can range from 40° to 50°, for example, it can be 45°.

Specifically, an angle formed between a liquid crystal alignment direction in the region of the first sub-electrode portion P1 and the first direction X can range from 220° to 230°, for example, it can be 225°; an angle formed between a liquid crystal alignment direction in the region of the second sub-electrode portion P2 and the first direction X can range from 130° to 140°, for example, it can be 135°; an angle formed between a liquid crystal alignment direction in the region of the third sub-electrode portion P3 and the first direction X can range from 310° to 320°, for example, it can be 315°; and an angle formed between a liquid crystal alignment direction in the region of the fourth sub-electrode portion P4 and the first direction X can range from 40° to 50°, for example, it can be 45°. By setting four alignment directions in the region of one pixel electrode 4, along with segmented bright and dark areas, an alignment mode of 8 domains in one sub-pixel can be formed when using the super UV photo alignment (SUVA) technology.

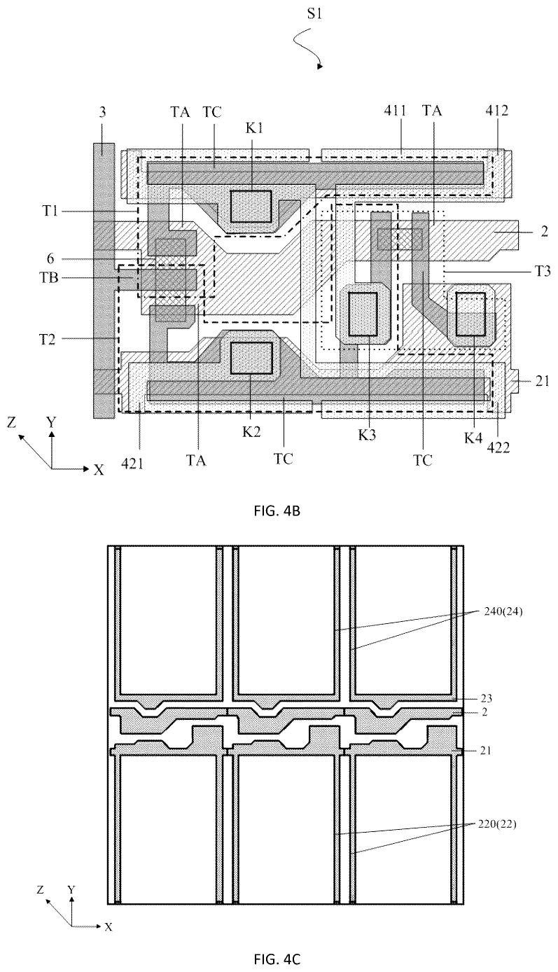

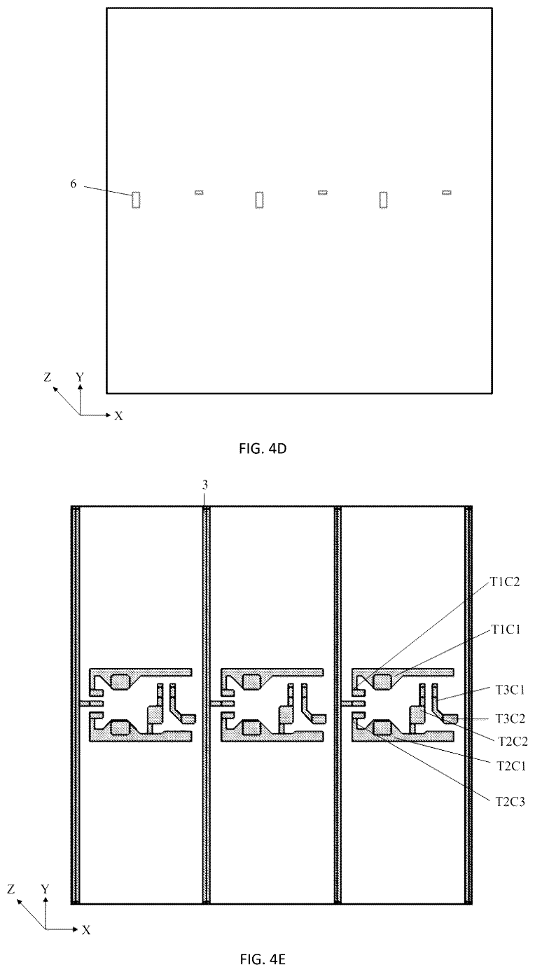

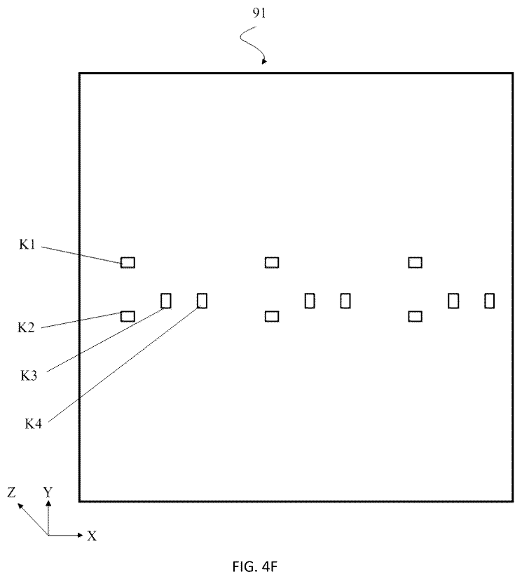

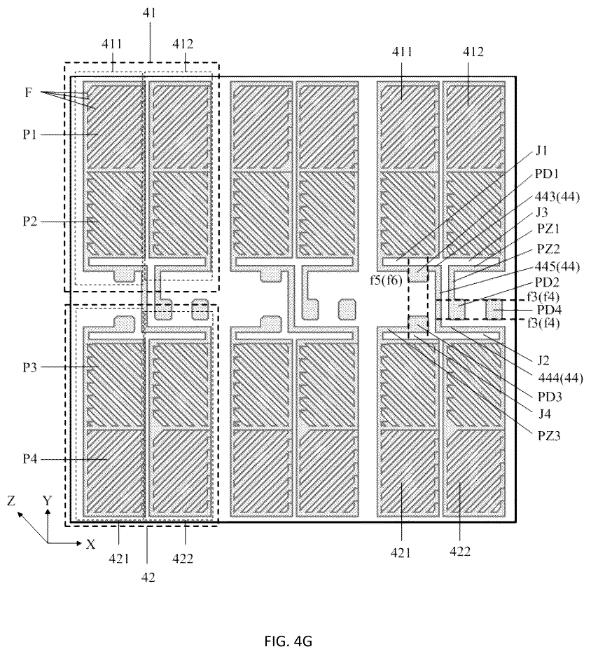

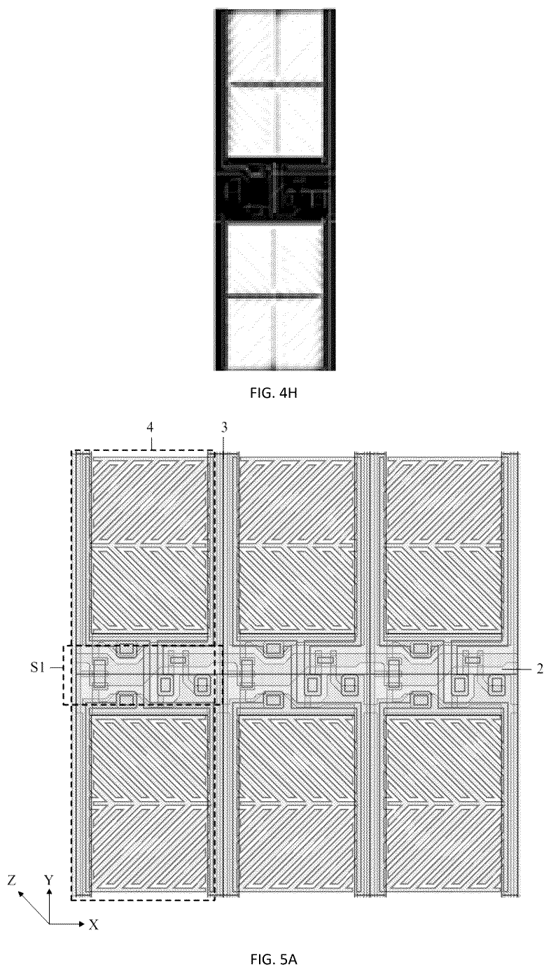

In a possible embodiment, as shown in FIGS. 1A-1G and 4A-4G, shapes of the orthographic projections of the first sub-pixel electrode 411, the second sub-pixel electrode 412, the third sub-pixel electrode 421, and the fourth sub-pixel electrode 422 on the base 1 all are a rectangular.

In a possible embodiment, as shown in FIGS. 2A-2G, the orthographic projection of the first sub-electrode portion P1, the orthographic projection of the second sub-electrode portion P2, the orthographic projection of the third sub-electrode portion P3, and the orthographic projection of the fourth sub-electrode portion P4 on the base 1 all have a trapezoidal shape. In the first sub-pixel electrode 411, top edges (i.e., short edges) of the first sub-electrode portion P1 of the trapezoid and the second sub-electrode portion P2 of the trapezoid face each other; in the fourth sub-pixel electrode 422, top edges (i.e., short edges) of the third sub-electrode portion P3 of the trapezoid and the fourth sub-electrode portion P4 of the trapezoid face each other; in the second sub-pixel electrode 412, bottom edges (i.e., long edges) of the first sub-electrode portion P1 of the trapezoid and the second sub-electrode portion P2 of the trapezoid face each other; and in the third sub-pixel electrode 421, bottom edges (i.e., long edges) of the third sub-electrode portion P3 of the trapezoid and the fourth sub-electrode portion P4 of the trapezoid face each other. In the embodiments of the disclosure, for the first pixel electrode 41 and the second pixel electrode 42, segmentation can be performed in a direction parallel to the extension direction of the slits F, which may have a better transmittance effect.

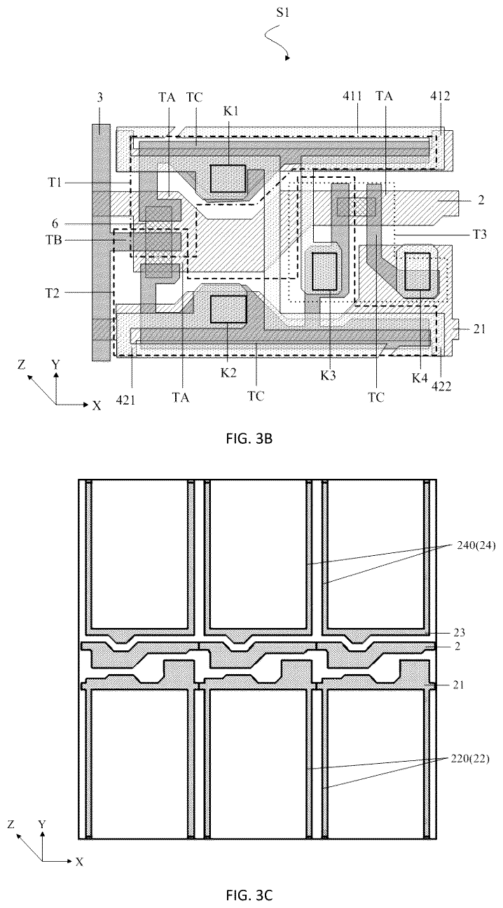

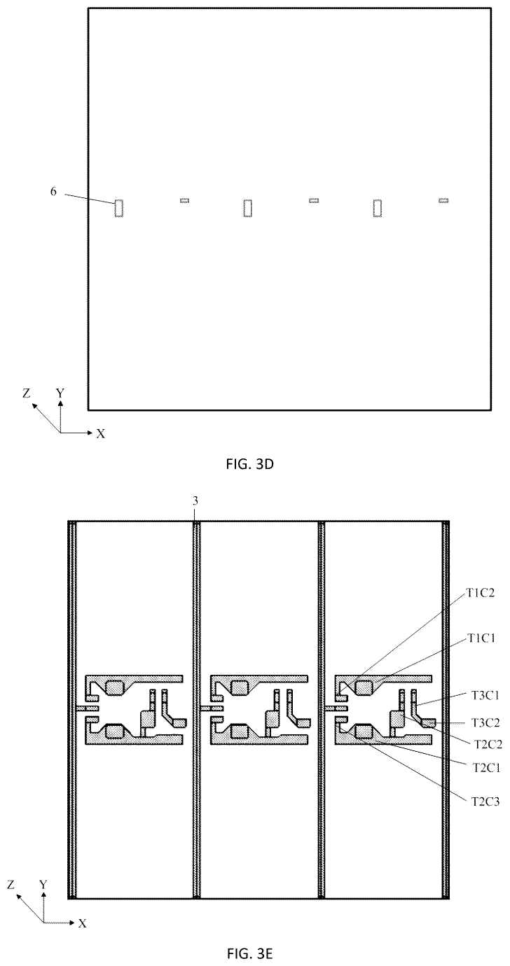

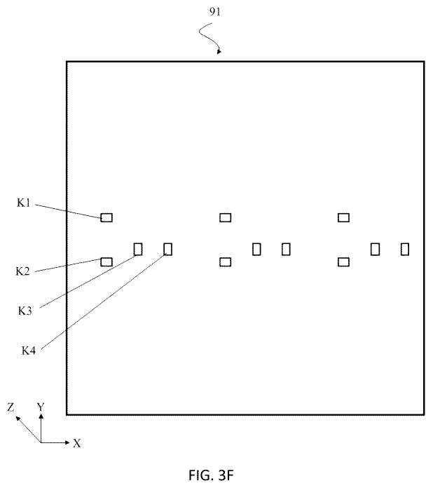

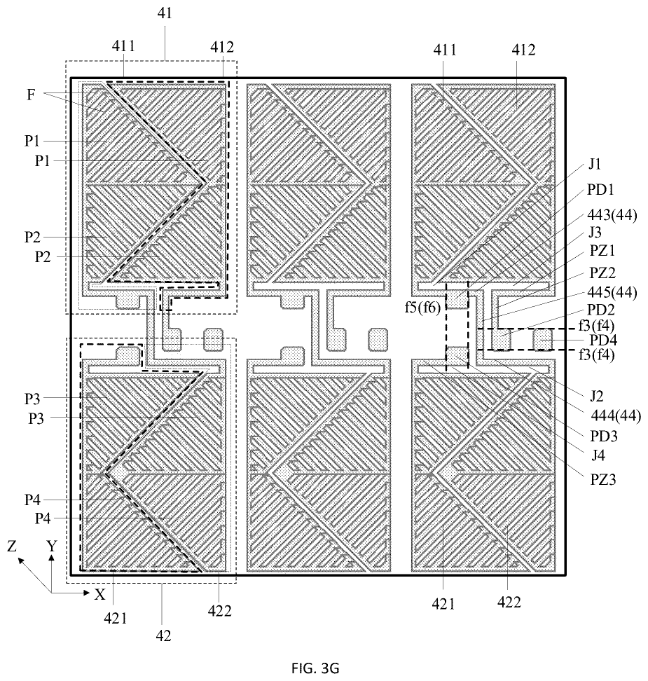

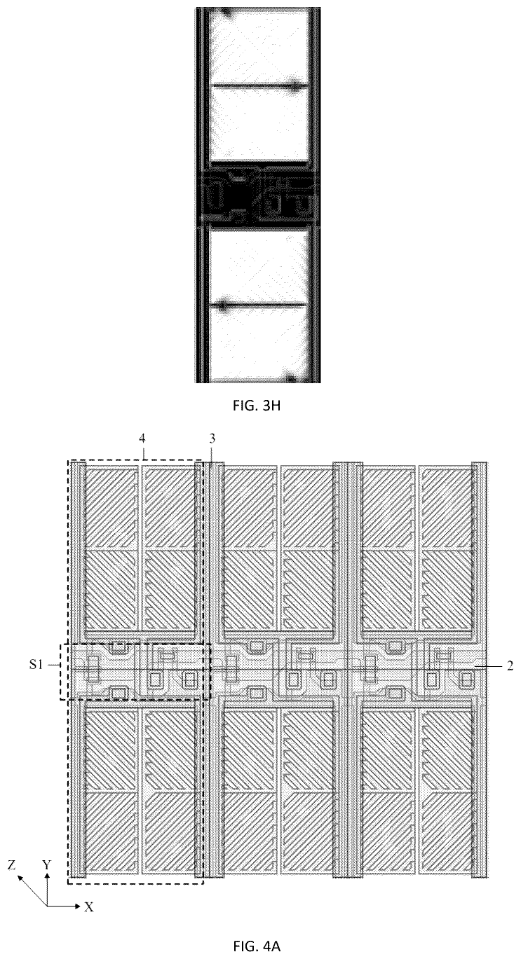

In a possible embodiment, as shown in FIGS. 3A-3G, the orthographic projections of the first sub-electrode portion P1, the second sub-electrode portion P2, the third sub-electrode portion P3, and the fourth sub-electrode portion P4 on the base 1 all have a trapezoidal shape. In the first sub-pixel electrode 411, bottom edges (long edges) of the first sub-electrode portion P1 of the trapezoid and the second sub-electrode portion P2 of the trapezoid face each other; in the fourth sub-pixel electrode 422, bottom edges (long edges) of the third sub-electrode portion P3 of the trapezoid and the fourth sub-electrode portion P4 of the trapezoid face each other; in the second sub-pixel electrode 412, top edges (i.e., short edges) of the first sub-electrode portion P1 of the trapezoid and the second sub-electrode portion P2 of the trapezoid face each other; and in the third sub-pixel electrode 421, top edges (i.e., short edges) of the third sub-electrode portion P3 of the trapezoid and the fourth sub-electrode portion P4 of the trapezoid face each other. In the embodiments of the disclosure, for the first pixel electrode 41 and the second pixel electrode 42, segmentation can be performed in a direction perpendicular to the extension direction of the slits F, in which may have a better transmittance effect.

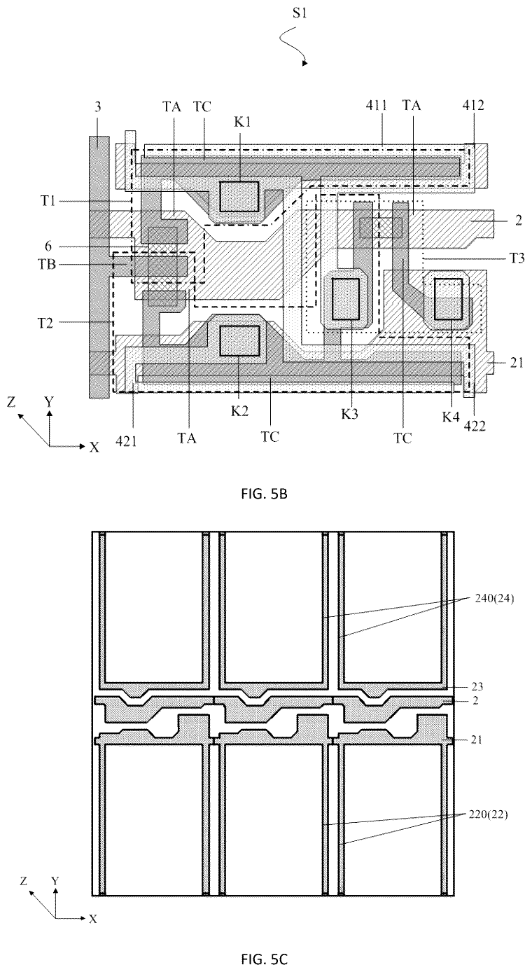

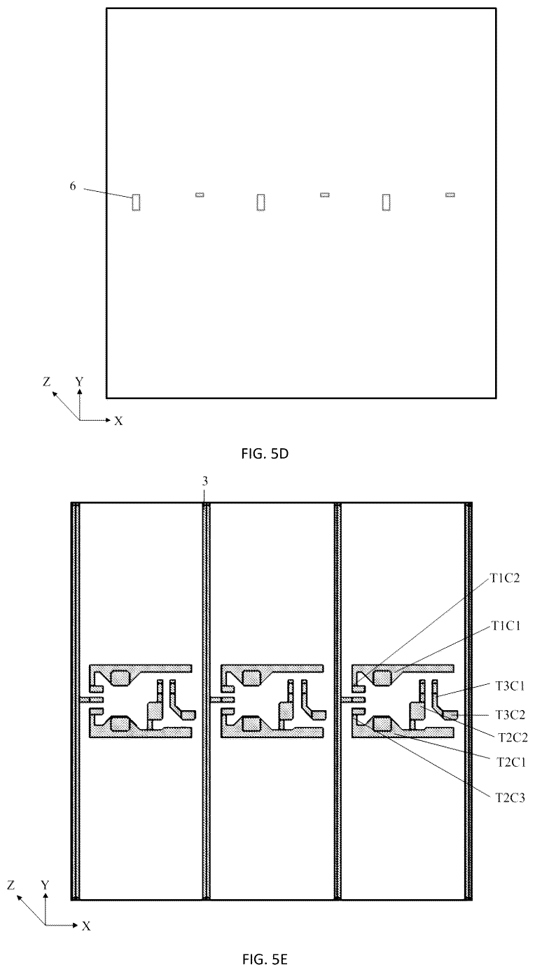

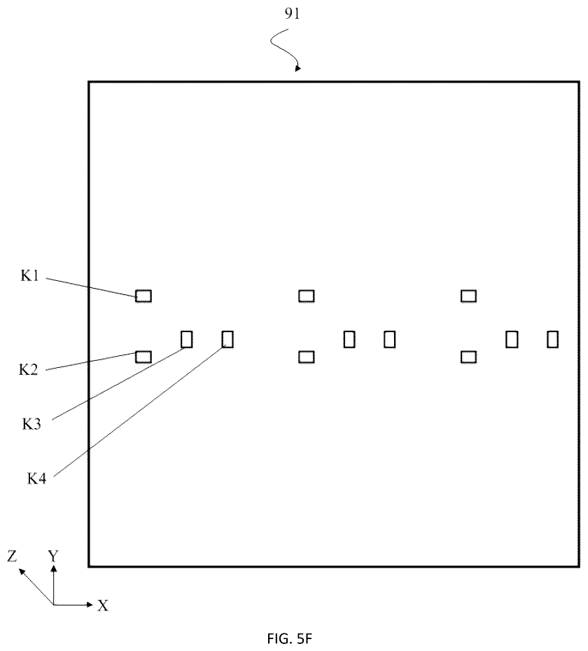

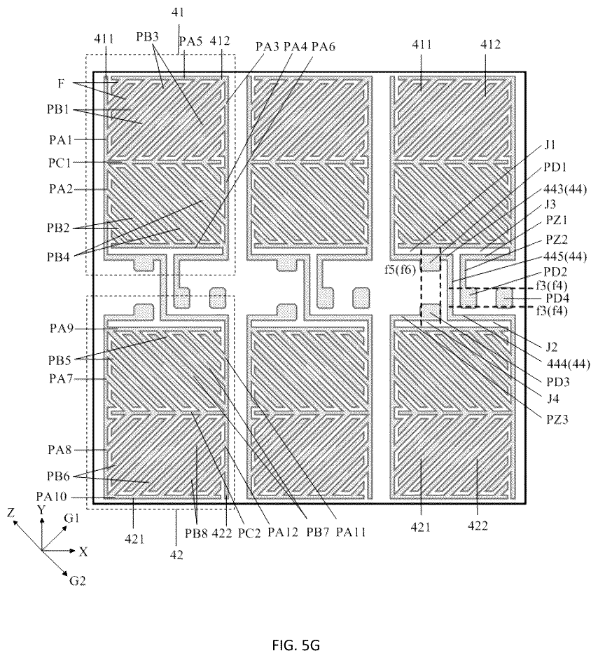

In a possible embodiment, as shown in FIGS. 5A to 5G, the first sub-pixel electrode 411 includes: a first body portion PA1 and a second body portion PA2 extending along the second direction Y and connected with each other, a first side portion PC1 extending along the first direction X, a plurality of first branch portions PB1 extending along a fourth direction G1 and starting from the first body portion PA1 and the first side portion PC1, and a plurality of second branch portions PB2 extending along a fifth direction G2 and starting from the second body portion PA2 and the first side portion PC1. The second sub-pixel electrode 412 includes: a third body portion PA3 and a fourth body portion PA4 extending along the second direction Y and connected with each other, a fifth body portion PA5 extending along the first direction X and connected with one end of the third body portion PA3, a sixth body portion PA6 extending along the first direction X and connected with one end of the fourth body portion PA4, a plurality of third branch portions PB3 extending along the fourth direction G1 and starting from the third body portion PA3 and the fifth body portion PA5, and a plurality of fourth branch portions PB4 extending along the fifth direction G2 and starting from the fourth body portion PA4 and the sixth body portion PA6. The plurality of first branch portions PB1 and the plurality of third branch portions PB3 are arranged in a form of crossed fingers, and the plurality of second branch portions PB2 and the plurality of fourth branch portions PB4 are arranged in the form of crossed fingers.

The third sub-pixel electrode 421 includes: a seventh body portion PA7 and an eighth body portion PA8 extending along the second direction Y and connected with each other, a ninth body portion PA9 extending along the first direction X and connected with one end of the seventh body portion PA7, a tenth body portion PA10 extending along the first direction X and connected with one end of the eighth body portion PA8, a plurality of fifth branch portions PB5 extending along the fourth direction G1 and starting from the seventh body portion PA7 and the ninth body portion PA9, and a plurality of sixth branch portions PB6 extending along the fifth direction G2 and starting from the eighth body portion PA8 and the tenth body portion PA10. The fourth sub-pixel electrode 422 includes: an eleventh body portion PA11 and a twelfth body portion PA12 extending along the second direction Y and connected with each other, a second side portion PC2 extending along the first direction X, a plurality of seventh branch portions PB7 extending along the fourth direction G1 and starting from the eleventh body portion PA11 and the second side portion PC2, and a plurality of eighth branch portions PB8 extending along the fifth direction G2 and starting from the twelfth body portion PA12 and the second side portion PC2. The plurality of fifth branch portions PB5 and the plurality of seventh branch portions PB7 are arranged in the form of crossed fingers, and the plurality of sixth branch portions PB6 and the plurality of eighth branch portions PB8 are arranged in the form of crossed fingers.

It should be noted that, for the array substrate structure corresponding to FIGS. 2A, 3A, and 5A provided in the embodiments of the disclosure, the display effect of different brightness can also be achieved by setting a first signal line 5 to release part of the voltage to the first signal line 5 through a third transistor T3. Similarly, for the array substrate shown in FIG. 1A provided in the embodiments of the disclosure, the first signal line 5 may not be set, and part of the voltage may be released to the first common line 21 through the third transistor T3 to achieve the display effect of different brightness, which is not limited in the embodiments of the disclosure.

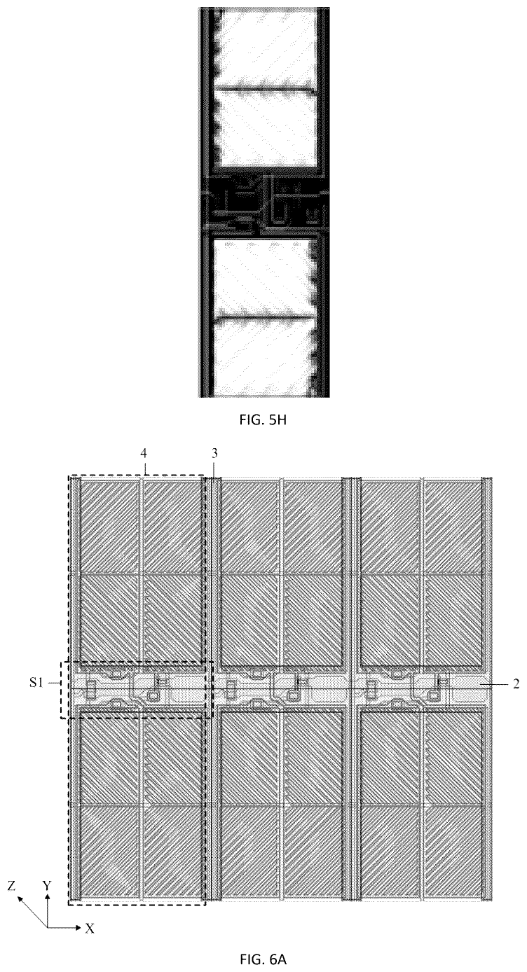

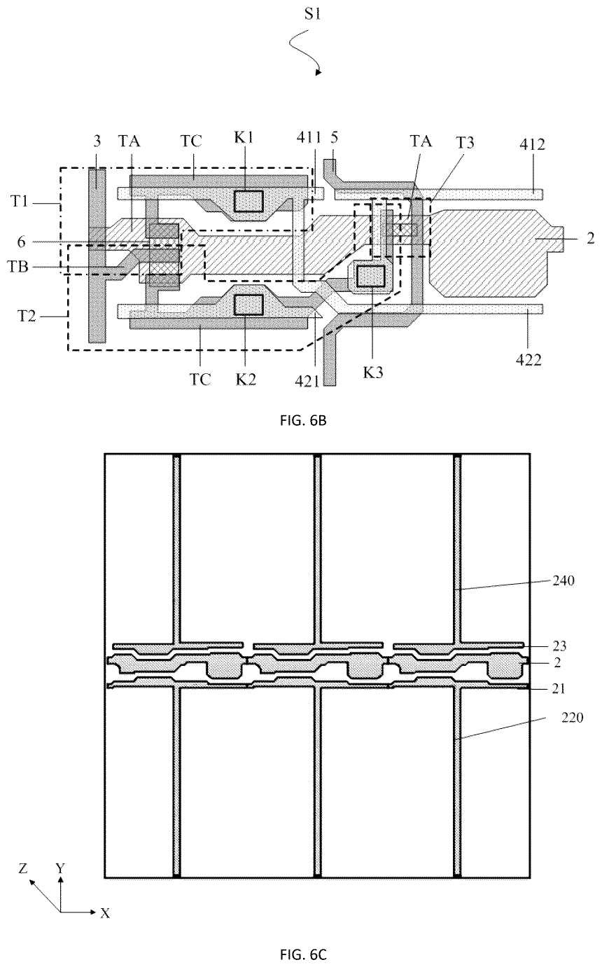

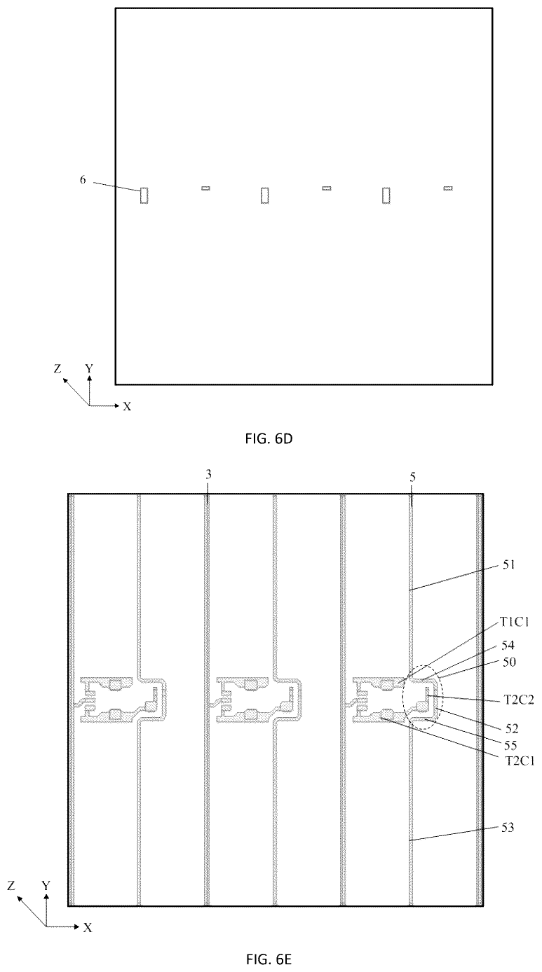

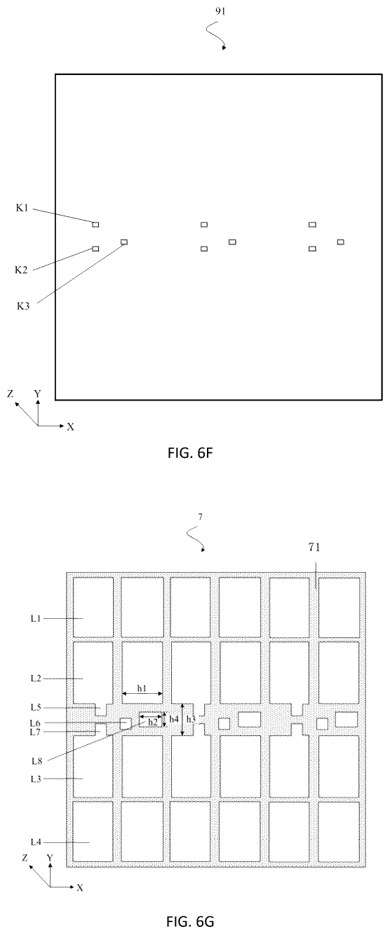

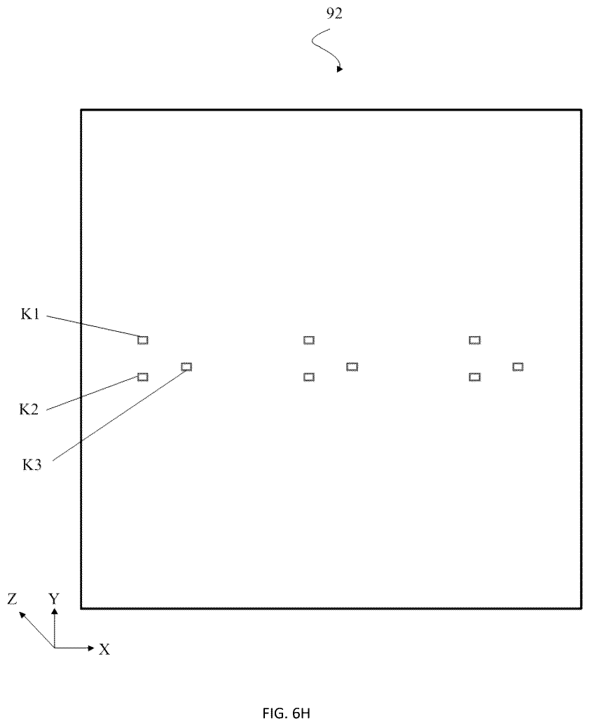

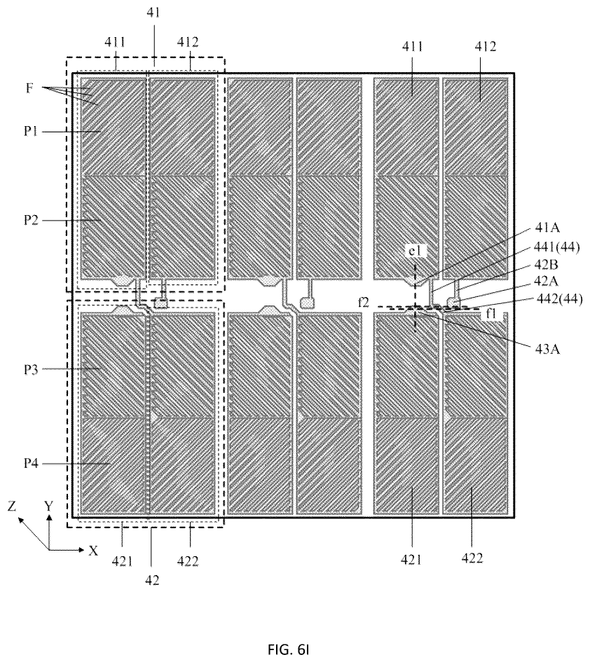

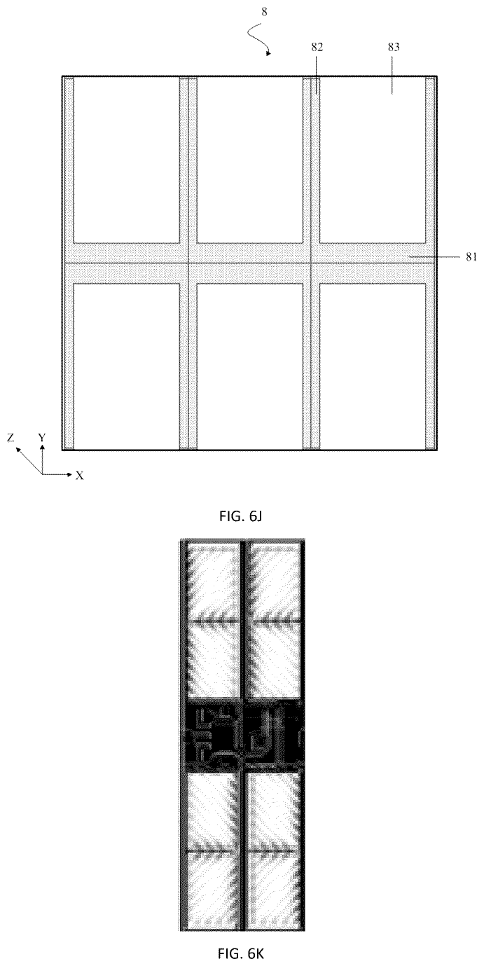

In a possible embodiment, as shown in FIGS. 6A to 6J, the array substrate further includes: a first conductive layer 7 disposed at a side of the pixel electrode 4 facing the base 1. The first conductive layer 7 includes a first hollowed-out structure L1, a second hollowed-out structure L2, a third hollowed-out structure L3, and a fourth hollowed-out structure L4. At least part of an orthographic projection of the first hollowed-out structure L1 on the base 1 overlaps with at least part of an orthographic projection of the first sub-electrode portion P1 on the base 1; at least part of an orthographic projection of the second hollowed-out structure L2 on the base 1 overlaps with at least part of an orthographic projection of the second sub-electrode portion P2 on the base 1; at least part of an orthographic projection of the third hollowed-out structure L3 on the base 1 overlaps with at least part of an orthographic projection of the third sub-electrode portion P3 on the base 1; and at least part of an orthographic projection of the fourth hollowed-out structure L4 on the base 1 overlaps with at least part of an orthographic projection of the fourth sub-electrode portion P4 on the base 1.

In the embodiments of the disclosure, for the vertical alignment (VA) display panel including the array substrate provided with a pixel electrode layer and the counter substrate provided with a common electrode layer, the first conductive layer 7 is further provided at the side of the pixel electrode 4 facing the base 1. The first conductive layer 7 has the first hollowed-out structure L1, the second hollowed-out structure L2, the third hollowed-out structure L3, and the fourth hollowed-out structure L4, which can make the liquid crystal twist more uniformly, reduce dark fringes corresponding to pixel electrodes, reduce the width of the black matrix, and improve the transmittance of the display panel. In addition, in addition to the vertical electric field in the array substrate formed by the pixel electrode and the common electrode, a horizontal electric field can be formed between the pixel electrode and the first conductive layer 7, which can increase the deflection indications of the liquid crystals and improve the color shift problem of the display panel.

Specifically, the first conductive layer 7 can be disposed between the base 1 and the layer of the pixel electrode 4. Specifically, the first conductive layer 7 can be applied with the same signal as the common electrode layer on the counter substrate. The first conductive layer 7 can specifically be a transparent electrode layer, and the material of the first conductive layer 7 can specifically be indium tin oxide (ITO).

In a possible embodiment, as shown in FIG. 6G, the first conductive layer 7 may further include a first conductive connecting portion 71. An orthographic projection of the first conductive connecting portion 71 on the base 1 covers the orthographic projection of the data line 3 and the orthographic projection of the gate line 2 on the base 1. In the embodiments of the disclosure, the orthographic projection of the first conductive connecting portion 71 on the base 1 covers the orthographic projection of the data line 3 and the gate line 2, so that the first conductive connecting portion 71 can shield the coupling capacitance between the pixel electrode and the data line 3, and the coupling capacitance between the pixel electrode and the gate line 2, avoiding setting the second common line 220 (and/or the fourth common line 240), or reducing the number or line width of the second common lines 220 (and/or the fourth common lines 240), thereby increasing the transmittance of the display panel.

In a possible embodiment, as shown in FIG. 6G, the first conductive layer 7 may further include a fifth hollowed-out structure L5, a sixth hollowed-out structure L6, a seventh hollowed-out structure L7, and an eighth hollowed-out structure L8. At least part of an orthographic projection of the fifth hollowed-out structure L5 on the base 1 may overlap with at least part of the orthographic projection of the first via hole K1 on the base 1, at least part of an orthographic projection of the sixth hollowed-out structure L6 on the base 1 may overlap with at least part of the orthographic projection of the second via hole K2 on the base 1, and at least part of an orthographic projection of the seventh hollowed-out structure L7 on the base 1 may overlap with at least part of the orthographic projection of the third via hole K3 on the base 1. The arrangement of the fifth hollowed-out structure L5, the sixth hollowed-out structure L6, and the seventh hollowed-out structure L7 is convenient for the conduction between the pixel electrodes 4 above the first conductive layer 7 and the transistors below the first conductive layer 7.

In the embodiments of the disclosure, the first conductive layer 7 may further include an eighth hollowed-out structure L8, which can prevent affecting the pixel charging rate by an overlap capacitance between the gate line 2 and the first conductive layer 7. If the first conductive layer 7 is made entirely hollow in the area of the gate line 2, it can cause light leakage. In the embodiments of the disclosure, the eighth hollowed-out structure L8 is just set in part of the area where the first conductive layer 7 overlaps with the gate line 2, which can reduce light leakage and reduce the overlap capacitance between the gate line 2 and the first conductive layer 7, ensuring the charging rate.

In a possible embodiment, a length h2 of the eighth hollowed-out structure L8 in the first direction X can be one-fifth to four-fifths of a length h1 of the second hollowed-out structure L2 in the first direction. In a possible embodiment, the length h2 of the eighth hollowed-out structure L8 in the first direction X can be one-fourth to three-fourths of the length h1 of the second hollowed-out structure L2 in the first direction. In a possible embodiment, the length h2 of the eighth hollowed-out structure L8 in the first direction X can be one-half of the length h1 of the second hollowed-out structure L2 in the first direction.

In a possible embodiment, a length h4 of the eighth hollowed-out structure L8 in the second direction Y can be one-fifth to four-fifths of a spacing h3 between the second hollowed-out structure L2 and the third hollowed-out structure L3. In a possible embodiment, the length h4 of the eighth hollowed-out structure L8 in the second direction Y can be one-fourth to three-fourths of the spacing h3 between the second hollowed-out structure L2 and the third hollowed-out structure L3. In a possible embodiment, the length h4 of the eighth hollowed-out structure L8 in the second direction Y can be one-half of the spacing h3 between the second hollowed-out structure L2 and the third hollowed-out structure L3.

In a possible embodiment, an extension line of an outer edge of the eighth hollowed-out structure L8 extending along the second direction Y and facing away from the sixth hollowed-out structure coincides with an extension line of an outer edge of the second hollowed-out structure L2 extending along the second direction Y.

In a possible embodiment, as shown in FIGS. 6A to 6J and FIG. 10, the data line 3 can be disposed at a side of the gate line 2 away from the base 1, the first conductive layer 7 can be disposed at a side of the data line 3 away from the gate line 2, and the pixel electrode 4 can be disposed at a side of the first conductive layer 7 away from the data line 3. A gate insulation layer can be provided between the layer of the gate line 2 and the layer of the data line 3, an active layer (the active layer may include an active pattern 6, and a material of the active layer may be amorphous silicon, low-temperature polysilicon, metal oxide, etc., without limitation here) can be provided between the gate insulation layer and the data line 3, a first insulation layer 91 can be provided between the data line 3 and the first conductive layer 7, and a second insulation layer 92 can be provided between the first conductive layer 7 and the pixel electrode 4.

As shown in FIGS. 1H, 2H, 3H, 4H, 5H, and 6K, embodiments of the disclosure perform optical simulations on different array substrate structures. By comparing the central horizontal dark fringes in the sub-pixels, it can be clearly seen that, among those array substrates where there is no first conductive layer 7 corresponding to FIGS. 1H, 2H, 3H, 4H and 5H, the structure corresponding to FIG. 2A has the highest transmittance.

Based on the same inventive conception, embodiments of the disclosure further provide a display panel, including: the array substrate provided in the embodiments of the disclosure, and a counter substrate arranged opposite to the array substrate, where the counter substrate is provided with a common electrode layer.

In a possible embodiment, as shown in FIGS. 6A to 6J and FIG. 10, the display panel may further include a black matrix 8. An orthographic projection of the black matrix 8 on the base 1 covers the orthographic projection of the gate line 2 on the base 1 and the orthographic projection of the data line 3 on the base 1. Specifically, the counter substrate may include a counter base 90, and the black matrix 8 may be disposed between the counter base 90 and the common electrode layer (not shown in FIG. 10).

In a possible embodiment, as shown in FIG. 10, the first conductive layer 7 is disposed at a side of the pixel electrode 4 away from the counter substrate. In the embodiments of the disclosure, the first conductive layer 7 is disposed at the side of the pixel electrode 4 away from the counter substrate, which can block (or shield) a first overlap capacitance between the pixel electrode 4 and the data line 3, and a second overlap capacitance between the pixel electrode 4 and the gate line 2, greatly reducing the risk of crosstalk. At the same time, due to the first conductive layer 7, a distance between the pixel electrodes 4 is reduced, allowing the overlap between the pixel electrodes 4 and the gate line 2, and the overlap between the pixel electrodes 4 and the data line 3, and reducing the risk of liquid crystal light leakage, thereby reducing the width of the black matrix, increasing the pixel aperture ratio, and improving the pixel transmittance.

Based on the same inventive conception, embodiments of the disclosure further provide a display apparatus, including the display panel as provided in the embodiments of the disclosure.

In specific implementation, in the embodiments of the disclosure, the display apparatus can be a mobile phone, tablet, TV, monitor, laptop, digital photo frame, navigation device, or any product or component with display functionality. Other essential components of the display apparatus are understood by those skilled in the art and are not discussed here, and should not be considered as limiting the disclosure.

Although the preferred embodiments of the disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of this disclosure.

Obviously, those skilled in the art can make various changes and modifications to embodiments of the disclosures without departing from the spirit and scope of embodiments of the disclosures. In this way, if these modifications and variations of the embodiments of the disclosure fall within the scope of the claims of the disclosure and equivalent technologies, the disclosure is also intended to include these modifications and variations.

1-39. (canceled)

40. An array substrate, comprising:
a base;
a plurality of gate lines at a side of the base and extending along a first direction;
a plurality of data lines extending along a second direction; and
a plurality of pixel electrodes; wherein the pixel electrode comprises a first pixel electrode at a side of the gate line and a second pixel electrode at the other side of the gate line; and the first pixel electrode comprises a first sub-pixel electrode and a second sub-pixel electrode arranged along the first direction, and the second pixel electrode comprises a third sub-pixel electrode and a fourth sub-pixel electrode arranged along the first direction;
wherein one of the first sub-pixel electrode or the second sub-pixel electrode is electrically connected with one of the third sub-pixel electrode or the fourth sub-pixel electrode.

41. The array substrate according to claim 40, further comprising: a plurality of transistors; wherein the transistors electrically connected with a same pixel electrode are electrically connected with a same data line and a same gate line;
the second sub-pixel electrode is at a side of the first sub-pixel electrode away from the data line in electrically connection;
the fourth sub-pixel electrode is at a side of the third sub-pixel electrode away from the data line in electrically connection; and
the first sub-pixel electrode is electrically connected with the fourth sub-pixel electrode.

42. The array substrate according to claim 41, further comprising: a first signal line extending along the second direction; wherein the plurality of transistors comprise a first transistor, a second transistor and a third transistor;
a control electrode of the first transistor is electrically connected with the gate line, a first electrode of the first transistor is electrically connected with the data line, and a second electrode of the first transistor is electrically connected with the first sub-pixel electrode and the fourth sub-pixel electrode;
a control electrode of the second transistor is electrically connected with the gate line, a first electrode of the second transistor is electrically connected with the data line, and a second electrode of the second transistor is electrically connected with the second sub-pixel electrode and the third sub-pixel electrode; and
a control electrode of the third transistor is electrically connected with the gate line, a first electrode of the third transistor shares the second electrode of the second transistor, and a second electrode of the third transistor shares the first signal line.

43. The array substrate according to claim 42, wherein the pixel electrode further comprises a first sub-pixel electrode convex portion connected with a side of the first sub-pixel electrode facing the third sub-pixel electrode;
wherein the second electrode of the first transistor is electrically connected with the first sub-pixel electrode through the first sub-pixel electrode convex portion;
wherein the pixel electrode further comprises a connection portion connecting the first sub-pixel electrode and the fourth sub-pixel electrode;
wherein the connection portion comprises a first connecting portion extending along the second direction and a second connecting portion extending along a third direction; wherein the third direction intersects with the first direction and the second direction;
wherein one end of the first connecting portion is electrically connected with one end of the first sub-pixel electrode facing the third sub-pixel electrode, and the other end of the first connecting portion is electrically connected with one end of the second connecting portion; and
the other end of the second connecting portion is electrically connected with one end of the fourth sub-pixel electrode facing the second sub-pixel electrode.

44. The array substrate according to claim 42, wherein the pixel electrode further comprises a third sub-pixel electrode convex portion connected with a side of the third sub-Attorney pixel electrode facing the first sub-pixel electrode;
wherein the second electrode of the second transistor is electrically connected with the third sub-pixel electrode through the third sub-pixel electrode convex portion;
wherein the pixel electrode further comprises a second sub-pixel electrode extension portion extending along the second direction, and a second sub-pixel electrode convex portion;
one end of the second sub-pixel electrode extension portion is electrically connected with one end of the second sub-pixel electrode facing the fourth sub-pixel electrode, and the other end of the second sub-pixel electrode extension portion is electrically connected with the second sub-pixel electrode convex portion; and
the second electrode of the second transistor is electrically connected with the second sub-pixel electrode through the second sub-pixel electrode convex portion;
wherein an extension direction of the second sub-pixel electrode extension portion is parallel to an extension direction of the first connecting portion.

45. The array substrate according to claim 44, wherein the second sub-pixel electrode convex portion has an outer edge extending along the first direction and located at a side away from the second sub-pixel electrode; and the third sub-pixel electrode convex portion has an outer edge extending along the first direction and located at a side away from the third sub-pixel electrode;
wherein an extension line of the outer edge of the second sub-pixel electrode convex portion coincides with an extension line of the outer edge of the third sub-pixel electrode convex portion; or, an extension line of the outer edge of the second sub-pixel electrode convex portion at least partially overlaps with the third sub-pixel electrode convex portion; or, an extension line of the outer edge of the third sub-pixel electrode convex portion at least partially overlaps with the second sub-pixel electrode convex portion;
or,
a line connecting a center of the third sub-pixel electrode convex portion and a center of the first sub-pixel electrode convex portion is parallel to the second direction.

46. The array substrate according to claim 44, wherein the second electrode of the second transistor comprises a first portion extending along the first direction, and a second portion extending along the second direction and electrically connected with one end of the first portion of the second transistor;
wherein an orthographic projection of the first portion of the second transistor on the base has an overlapping area with an orthographic projection of the third sub-pixel electrode convex portion on the base; and
an orthographic projection of the second portion of the second transistor on the base has an overlapping area with an orthographic projection of the second sub-pixel electrode convex portion on the base;
wherein at least part of the orthographic projection of the second portion of the second transistor on the base overlaps with at least part of an orthographic projection of the second sub-pixel electrode extension portion on the base.

47. The array substrate according to claim 46, wherein the first signal line comprises a recessed portion;
wherein at least part of the orthographic projection of the second portion of the second transistor on the base is located in a region surrounded by an orthographic projection of the recessed portion on the base;
wherein the first signal line comprises:
a first signal portion, a second signal portion, and a third signal portion that are sequentially arranged along the second direction;
a fourth signal portion extending along the first direction and connected with the second signal portion and the first signal portion; and
a fifth signal portion extending along the first direction and connected with the second signal portion and the third signal portion;
wherein an extension line of the first signal portion coincides with an extension line of the third signal portion, and an extension line of the second signal portion does not coincide with the extension line of the first signal portion;
the second signal portion, the fourth signal portion, and the fifth signal portion form the recessed portion; and
the fourth signal portion and/or the fifth signal portion at least partially overlaps with the pixel electrode.

48. The array substrate according to claim 41, further comprising a first common line located at a side of the gate line and extending along the first direction;
wherein the plurality of transistors comprise a first transistor, a second transistor and a third transistor electrically connected with the data line;
a control electrode of the first transistor is electrically connected with the gate line, a first electrode of the first transistor is electrically connected with the data line, and a second electrode of the first transistor is electrically connected with the first sub-pixel electrode and the fourth sub-pixel electrode;
a control electrode of the second transistor is electrically connected with the gate line, a first electrode of the second transistor is electrically connected with the data line, and a second electrode of the second transistor is electrically connected with the second sub-pixel electrode and the third sub-pixel electrode; and
a control electrode of the third transistor is electrically connected with the gate line, a first electrode of the third transistor shares the second electrode of the second transistor, and a second electrode of the third transistor is electrically connected with the first common line.

49. The array substrate according to claim 48, wherein the pixel electrode further comprises a connection portion connecting the first sub-pixel electrode and the fourth sub-pixel electrode, and a first lapping portion connected with the connection portion;
wherein the connection portion comprises: a third connecting portion and a fourth connecting portion extending along the first direction, and a fifth connecting portion extending along the second direction;
one end of the third connecting portion is connected with the first sub-pixel electrode, one end of the fourth connecting portion is connected with the fourth sub-pixel electrode, one end of the fifth connecting portion is connected with the other end of the third connecting portion, and the other end of the fifth connecting portion is connected with the other end of the fourth connecting portion;
the first lapping portion is electrically connected with the third connecting portion and located at a side away from the first sub-pixel electrode connected; and
the second electrode of the first transistor is electrically connected with the first sub-pixel electrode and the fourth sub-pixel electrode through the first lapping portion;
wherein the pixel electrode further comprises a first transfer portion extending along the first direction, a second transfer portion extending along the second direction, and a second lapping portion;
one end of the first transfer portion is electrically connected with one end of the second sub-pixel electrode facing the fourth sub-pixel electrode, and the other end of the first transfer portion is electrically connected with one end of the second transfer portion;
the other end of the second transfer portion is electrically connected with the second lapping portion; and
the second electrode of the second transistor is electrically connected with the second sub-pixel electrode through the second lapping portion;
wherein an extension direction of the second transfer portion is parallel to an extension direction of the fifth connecting portion.

50. The array substrate according to claim 49, wherein the pixel electrode further comprises a third transfer portion extending along the first direction and a third lapping portion;
one end of the third transfer portion is electrically connected with one end of the third sub-pixel electrode facing the first sub-pixel electrode, and the other end of the third transfer portion is electrically connected with the third lapping portion; and
the second electrode of the second transistor is electrically connected with the third sub-pixel electrode through the third lapping portion;
wherein a first gap is provided between the third connecting portion and the first pixel electrode;
a second gap is provided between the fourth connecting portion and the second pixel electrode;
a third gap is provided between the first transfer portion and the first pixel electrode; and
a fourth gap is provided between the third transfer portion and the second pixel electrode
wherein the array substrate further comprises a fourth lapping portion;
wherein the second electrode of the third transistor is electrically connected with the first common line through the fourth lapping portion;
wherein the fourth lapping portion has an outer edge extending along the first direction;
the second lapping portion has an outer edge extending along the first direction;
the first lapping portion has an outer edge extending along the second direction; and
the third lapping portion has an outer edge extending along the second direction;
wherein an extension line of the outer edge of the fourth lapping portion coincides with an extension line of the outer edge of the second lapping portion; and
an extension line of the outer edge of the first lapping portion coincides with an extension line of the outer edge of the third lapping portion.

51. The array substrate according to claim 50, wherein the second electrode of the first transistor comprises a first portion extending along the first direction;
wherein an orthographic projection of the first portion of the first transistor on the base has an overlapping area with an orthographic projection of the first lapping portion on the base;
wherein the second electrode of the second transistor comprises: a first portion extending along the first direction, and a second portion extending along the second direction and electrically connected with one end of the first portion of the second transistor;
wherein an orthographic projection of the first portion of the second transistor on the base has an overlapping area with an orthographic projection of the third lapping portion on the base; and
an orthographic projection of the second portion of the second transistor on the base has an overlapping area with an orthographic projection of the second lapping portion on the base.

52. The array substrate according to claim 41, further comprising a first common line located at a side of the gate line and extending along the first direction;
wherein the first common line is disconnected at an intersection with the date line;
wherein the array substrate further comprises a second common line group connected with the first common line and extending towards a side away from the gate line;
wherein the second common line group comprises two second common lines;
wherein an orthographic projection of the data line on the base has an overlapping area with an orthographic projection of a gap between the two second common lines of a same second common line group on the base;
wherein the array substrate further comprises a third common line located at the other side of the gate line and extending along the first direction, and a fourth common line group connected with the third common line and extending towards a side away from the gate line;
wherein the third common line is disconnected at an intersection with the data line;
the fourth common line group comprises two fourth common lines;
the orthographic projection of the data line on the base has an overlapping area with an orthographic projection of a gap between the two fourth common lines of a same fourth common line group on the base.

53. The array substrate according to claim 52, further comprising a fifth common line extending along the first direction and electrically connected with the second common lines; wherein an orthographic projection of the fifth common line on the base passes through a central area of an orthographic projection of the second pixel electrode on the base; and/or,
wherein the array substrate further comprises a sixth common line extending along the first direction and electrically connected with the fourth common lines; wherein an orthographic projection of the sixth common line on the base passes through a central area of an orthographic projection of the first pixel electrode on the base.

54. The array substrate according to claim 40, wherein the first sub-pixel electrode and the second sub-pixel electrode each comprises: a first sub-electrode portion and a second sub-electrode portion arranged along the second direction;
the third sub-pixel electrode and the fourth sub-pixel electrode each comprises: a third sub-electrode portion and a fourth sub-electrode portion arranged along the second direction;
the first sub-electrode portion, the second sub-electrode portion, the third sub-electrode portion, and the fourth sub-electrode portion each has multiple slits; and
an extension direction of the slits in the first sub-electrode portion is same as an extension direction of the slits in the fourth sub-electrode portion, and an extension direction of the slits in the second sub-electrode portion is same as an extension direction of the slits in the third sub-electrode portion;
wherein a length of each of the slits in a direction perpendicular to the extension direction range from 2 μm to 4 μm.

55. The array substrate according to claim 54, wherein shapes of orthographic projections of the first sub-pixel electrode, the second sub-pixel electrode, the third sub-pixel electrode, and the fourth sub-pixel electrode on the base all are a rectangular; or,
wherein an orthographic projection of the first sub-electrode portion, an orthographic projection of the second sub-electrode portion, an orthographic projection of the third sub-electrode portion, and an orthographic projection of the fourth sub-electrode portion on the base all have a trapezoidal shape; wherein in the first sub-pixel electrode, top edges of the first sub-electrode portion of the trapezoidal shape and the second sub-electrode portion of the trapezoidal shape face each other; in the fourth sub-pixel electrode, top edges of the third sub-electrode portion of the trapezoid and the fourth sub-electrode portion of the trapezoid face each other; in the second sub-pixel electrode, bottom edges of the first sub-electrode portion of the trapezoidal shape and the second sub-electrode portion of the trapezoidal shape face each other; and in the third sub-pixel electrode, bottom edges of the third sub-electrode portion of the trapezoid and the fourth sub-electrode portion of the trapezoid face each other; or,
wherein an orthographic projection of the first sub-electrode portion, an orthographic projection of the second sub-electrode portion, an orthographic projection of the third sub-electrode portion, and an orthographic projection of the fourth sub-electrode portion on the base all have a trapezoidal shape; wherein in the first sub-pixel electrode, bottom edges of the first sub-electrode portion of the trapezoidal shape and the second sub-electrode portion of the trapezoidal shape face each other; in the fourth sub-pixel electrode, bottom edges of the third sub-electrode portion of the trapezoid and the fourth sub-electrode portion of the trapezoid face each other; in the second sub-pixel electrode, top edges of the first sub-electrode portion of the trapezoidal shape and the second sub-electrode portion of the trapezoidal shape face each other; and in the third sub-pixel electrode, top edges of the third sub-electrode portion of the trapezoid and the fourth sub-electrode portion of the trapezoid face each other.

56. The array substrate according to claim 54, wherein the first sub-pixel electrode comprises:
a first body portion and a second body portion extending along the second direction and connected with each other,
a first side portion extending along the first direction,
a plurality of first branch portions extending along a fourth direction and starting from the first body portion and the first side portion, and
a plurality of second branch portions extending along a fifth direction and starting from the second body portion and the first side portion;
wherein the second sub-pixel electrode comprises:
a third body portion and a fourth body portion extending along the second direction and connected with each other,
a fifth body portion extending along the first direction and connected with one end of the third body portion,
a sixth body portion extending along the first direction and connected with one end of the fourth body portion,
a plurality of third branch portions extending along the fourth direction and starting from the third body portion and the fifth body portion, and
a plurality of fourth branch portions extending along the fifth direction and starting from the fourth body portion and the sixth body portion;
wherein the plurality of first branch portions and the plurality of third branch portions are arranged in a form of crossed fingers, and the plurality of second branch portions and the plurality of fourth branch portions are arranged in the form of crossed fingers;
wherein the third sub-pixel electrode comprises:
a seventh body portion and an eighth body portion extending along the second direction and connected with each other,
a ninth body portion extending along the first direction and connected with one end of the seventh body portion,
a tenth body portion extending along the first direction and connected with one end of the eighth body portion,
a plurality of fifth branch portions extending along the fourth direction and starting from the seventh body portion and the ninth body portion, and
a plurality of sixth branch portions extending along the fifth direction and starting from the eighth body portion and the tenth body portion;
wherein the fourth sub-pixel electrode comprises:
an eleventh body portion and a twelfth body portion extending along the second direction and connected with each other,
a second side portion extending along the first direction,
a plurality of seventh branch portions extending along the fourth direction and starting from the eleventh body portion and the second side portion, and
a plurality of eighth branch portions extending along the fifth direction and starting from the twelfth body portion and the second side portion;
wherein the plurality of fifth branch portions and the plurality of seventh branch portions are arranged in the form of crossed fingers, and the plurality of sixth branch portions and the plurality of eighth branch portions are arranged in the form of crossed fingers.

57. The array substrate according to claim 40, further comprising a first conductive layer at a side of the pixel electrode facing the base;
wherein the first conductive layer comprises a first hollowed-out structure, a second hollowed-out structure, a third hollowed-out structure, and a fourth hollowed-out structure;
wherein at least part of an orthographic projection of the first hollowed-out structure on the base overlaps with at least part of an orthographic projection of the first sub-electrode portion on the base;
at least part of an orthographic projection of the second hollowed-out structure on the base overlaps with at least part of an orthographic projection of the second sub-electrode portion on the base;
at least part of an orthographic projection of the third hollowed-out structure on the base overlaps with at least part of an orthographic projection of the third sub-electrode portion on the base; and
at least part of an orthographic projection of the fourth hollowed-out structure on the base overlaps with at least part of an orthographic projection of the fourth sub-electrode portion on the base.

58. A display panel, comprising the array substrate according to claim 40, and a counter substrate arranged opposite to the array substrate; wherein the counter substrate is provided with a common electrode layer.

59. A display apparatus, comprising the display panel according to claim 58.
